(19) United States
(12) Patent Application Publication
(10) Pub. No.: US 2026/0360666 A1
(43) Pub. Date: Nov. 12, 2026

(54) DISTURBANCE COMPENSATION FOR CHARGED PARTICLE BEAM DEVICES

(71) Applicant: Carl Zeiss SMT GmbH, Oberkochen (DE)

(72) Inventors: Michael Budach, Hanau (DE); Benjamin Rein, Gorxheimertal (DE); Daniel Ploeger, Darmstadt (DE); Andreas Krugmann, Rossdorf (DE)

(21) Appl. No.: 19/734,101

(22) Filed: Jul. 8, 2026

Related U.S. Application Data
(63) Continuation of application No. PCT/EP2024/050592, filed on Jan. 11, 2024.

(51) Int. Cl. H01J 37/304; H01J 37/302

(52) U.S. Cl. CPC H01J 37/304; H01J 37/302; H01J 2237/30455

(57) ABSTRACT

Charged particle beam devices, e.g., for repair tasks, are subject to disturbances. A sensor output of one or more sensors is used to compensate the disturbances, e.g., while executing a manipulation mode for repairing defects on a lithography mask.

### CROSS-REFERENCE TO RELATED APPLICATION

This application is a continuation of and claims benefit under 35 U.S.C. § 120 from PCT Application No. PCT/EP2024/050592, filed on Jan. 11, 2024, the entire content of which is incorporated herein by reference.

### TECHNICAL FIELD

Various examples of the disclosure generally relate to a charged particle beam device and to an operating method for a charged particle beam device. Various examples specifically pertain to compensation of disturbances during operation of the charged particle beam device.

### BACKGROUND

Charged particle beam devices can be used for microscopy or manipulation, e.g., of semiconductor structures. Charged particles that can be used in a charged particle beam device include: electrons, positrons, muons, and ions. Examples of charged particle beam devices include: Scanning Electron Microscope (SEM); Focused Ion Beam (FIB) device; SEM including multiple beams, sometimes also referred to as multi-SEM.

For instance, JP 2004-079334 discloses electron-beam devices such as electron microscopes and electron-beam lithography devices that are equipped with semiconductor electron-beam detectors that detect electron beams. Multiple electron-beam sensors are arranged on opposing sides of a mounting substrate, thereby allowing for easy replacement of a semiconductor electron-beam detector upon replacing the semiconductor electron-beam detector.

Images of an object can be recorded using particle microscopes. In this way, for example the structure of the surface can be analyzed (inspection mode). Also, it is possible to modify a specimen, e.g., by removing material or by depositing material (manipulation mode). For instance, charged particle beam devices can be used to modify/manipulate lithography masks.

Then, charged particle beam devices are sometimes referred to as repair devices. Examples with respect to such repair devices are disclosed in US20200912914, the disclosure of which is incorporated herein by reference.

US 2018/0277361 A1 discloses a method of material deposition onto a sample including directing a charged particle beam towards a substrate to induce a deposition from the precursor gas of a protective layer above a region of interest. The protective layer can be a composite mix of material having a spot array that substantially matches a spot array of the substrate.

Often, disturbances cause irregularities in the operation of a charged particle beam device. External disturbances, e.g., from varying temperature, pressure, vibrations, etc. often affect a beam positioning of the particle beam of the charged particle beam device with respect to the sample stage.

A closed-loop control to compensate for the beam offset is not always possible, because measuring a beam offset of the charged particle beam is not possible or only be possible to a limited degree during operation in the inspection or manipulation mode. Forward-compensation of individual disturbances is known in the prior art. This is explained below.

For instance, JP 2003173755 discloses a charged particle beam device that includes an active magnetic field source that is configured to cancel disturbances caused by an external magnetic field. However, it has been observed that only insufficient compensation of the placement offset is achieved using the techniques disclosed in JP 2003173755.

U.S. Pat. No. 3,842,272 discloses a scanning charged particle microprobe system. A beam scans the specimen in a predetermined pattern. Spurious external electric and magnetic fields can be compensated by applying beam correction signals to the beam scanning means. Again, using such techniques as disclosed in U.S. Pat. No. 3,842,272, only insufficient compensation of placement offsets caused by this spurious external electric and magnetic fields is achieved.

U.S. Pat. No. 6,043,490 discloses a charged particle beam apparatus including means for individually detecting x- and y-components of mechanical vibration and means for correcting x- and y-scanning signals so as to remove and influence of the mechanical vibration. Employing the techniques of U.S. Pat. No. 6,043,590 only yields limited abilities to compensate a placement offset of a beam of the charged particle beam device due to disturbances.

U.S. Pat. No. 9,601,310 discloses a charged particle microscope that includes a barometric pressure sensor. A control procedure is used to compensate for a relative position error between the charged particle beam and the specimen holder based on a sensor signal from the barometric sensor. Only limited accuracy in the compensation of the placement offset due to disturbances is achieved using the technologies disclosed by U.S. Pat. No. 9,601,310.

U.S. Pat. No. 4,698,503 discloses a refocusing apparatus used in a transmission electron microscope operable to deal with an electron-beam sensor output signal at discrete irradiation angles.

### SUMMARY

Accordingly, a need exists for advanced techniques of compensating a beam offset of a beam of a charged particle beam device on the sample stage that is caused by multiple disturbances. Accordingly, with the increasing requirement on resolution a need exists for advanced techniques of compensating a beam aberration of beam blurring of a beam of a charged particle beam device that is caused by multiple disturbances.

This need is met by the features of the independent claims. The features of the dependent claims define embodiments.

According to examples, a charged particle beam device includes a beam source, at least one beam deflection unit, and a sample stage.

The charged particle beam device, in some examples, implements a charged particle beam repair device, in which case the charged particle beam repair device further includes a precursor gas source. The precursor gas source includes a gas supply, a supply valve, and a supply nozzle located in the vicinity of the sample stage. Sometimes, the charged particle beam repair device can include multiple precursor gas sources, to thereby supply different types of precursor gases.

Each of the at least one beam deflection unit is configured to deflect a beam of charged particles—e.g., electrons or ions—to position the beam on the sample stage.

The charged particle beam repair device includes multiple sensors. These multiple sensors are configured to measure multiple disturbances of multiple physical quantities that each affect a beam offset of the beam on the sample stage.

The charged particle beam repair device also includes at least one control unit, e.g., a microprocessor or a processor that is configured to execute program code that is loaded from a memory. Embedded electronics may be used. In Field Program Gated Array (FPGA) may be used to implement the control unit.

The at least one control unit has various tasks of beam control and process control.

The at least one control unit can also process the sensor output provided by the multiple sensors, to thereby determine one or more compensation signals to counteract the beam offset.

The at least one control unit, in some examples, e.g., when a manipulation mode is performed to accomplish a repair task of a sample, is also configured to provide, to the beam source, the at least one beam deflection unit, and the precursor gas source, control signals to implement an electron beam-induced manipulation of the sample that is mounted to the sample stage.

The at least one control unit is configured to provide, e.g., during this electron-beam-induced manipulation or when operating in an imaging mode, the one or more compensation signals to at least one of the beam source, the at least one beam deflection unit, the sample stage or one or more compensator modules of the charged particle beam repair device or arranged in its surrounding.

Such techniques enable reduction or full compensation of disturbances during operation of the charged particle beam device, e.g., while operating in an imaging mode or a manipulation mode. For instance, a semiconductor mask or another repair object can be subjected to one or more repair tasks in the manipulation mode. By reducing or compensating the disturbances while executing the manipulation, damage to the mask can be avoided.

A method of manipulating a sample that is mounted to a sample stage of a charged particle beam repair device is disclosed. The charged particle beam repair device includes a beam source, at least one beam deflection unit, a precursor gas source, and the sample stage. The at least one beam deflection unit is configured to deflect a beam of charged particles that originate from the beam source, to thereby position the beam on the sample stage. The method includes obtaining a sensor output of multiple sensors of the charged particle beam repair device. The multiple sensors measure multiple disturbances of multiple physical quantities that each affect a beam offset of the beam on a sample stage. The method also includes determining, based on the sensor output of the multiple sensors, one or more compensation signals to counteract the beam offset. The method also includes providing, to the beam source, the at least one beam deflection unit, and the precursor gas source control signals that implement an electron-beam-induced manipulation of the sample. The method further includes providing, during the electron-beam-induced manipulation, the one or more compensation signals to at least one of the beam source, the at least one beam deflection unit, the sample states, or the one or more compensator modules. A computer program or a computer-program product or a computer-readable storage medium includes program code. The program code can be loaded and executed by at least one processor. The at least one processor, upon loading and executing the program code, is configured to perform such method of manipulating the sample.

In some examples, a charged particle beam device includes a beam source, at least one beam deflection unit, and a sample stage. The at least one beam deflection unit is configured to deflect a beam that originates from the beam source, to thereby position the beam on the sample stage. The charged particle beam device includes multiple sensors configured to measure multiple disturbances of multiple physical quantities that each affect a beam offset of the beam on the sample stage. The at least one control unit is configured to determine, based on a sensor output of the multiple sensors, meta data that is indicative of one or more compensation operations to counteract the beam offset in imaging data that is acquired by the charged particle beam repair device operating in an imaging mode. The meta data can be stored in association with the image data.

A method of post-processing image data that is acquired by a charged particle beam device is disclosed. The charged particle beam device includes a beam source, at least one beam deflection unit, and a sample stage. The at least one beam deflection unit is configured to deflect a beam that originates from the beam source to position the beam on the sample stage. The method includes obtaining a sensor output for multiple sensors of the charged particle beam device. The multiple sensors measure multiple disturbances of multiple physical quantities that each affect a beam offset of the beam on the sample stage. The method also includes determining meta data based on the sensor output of the multiple sensors. The meta data is indicative of one or more compensation operations to counteract the beam offset in image data. The image data is acquired by the charged particle beam device when operating in an imaging mode. The method also includes post-processing the image data based on the meta data and in accordance with the one or more compensation operations.

The multiple sensors may include one or more laser interferometers, e.g., configured to measure the position of the sample stage relative to the vacuum chamber; and/or configured to measure the position of the stage sample relative to the particle beam column of the charged particle beam repair device. A spatial resolution may be not worse than 10 nm, optionally not worse than 2 nm.

The multiple sensors may include one or more linear encoders, e.g., configured to measure the position of the sample stage relative to the vacuum chamber; and/or configured to measure the position of the stage sample relative to the particle beam column of the charged particle beam repair device. A spatial resolution may be not worse than 10 nm, optionally not worse than 2 nm.

The multiple sensors may include one or more accelerometers.

The multiple sensors may include one or more acoustic sensors.

The multiple sensors may be configured to sense one or more components of a magnetic field.

The multiple sensors may include one or more sensors configured to supply a signal synchronized with the AC mains voltage.

At least one of the multiple sensors may be arranged inside a vacuum chamber of the charged particle beam repair device.

At least one of the multiple sensors may be arranged outside a vacuum chamber of the charged particle beam repair device.

The control unit may be configured to provide the one or more compensation signals at real time. I.e., a processing stack from acquiring a sensor output of the multiple sensors to providing the respective one or more compensation signals may operate at the latency below a millisecond or even below a microsecond. A computer program or a computer-program product or a computer-readable storage medium includes program code. The program code can be loaded and executed by at least one processor. The at least one processor, upon loading and executing the program code, is configured to perform such method of post processing image data.

Such techniques enable reduction or full compensation of disturbances in the postprocessing of imaging data that is acquired by the charged particle beam device, e.g., while operating in the imaging mode.

A beam deflection unit as disclosed herein can be an electrostatic or magnetic/magnetostatic beam deflection unit. In particular, a beam deflection unit can be an electrostatic deflection system which is arranged after the last lens of the electron microscope (octupole). This type of electrostatic or magnetic compensation is not subject to mechanical inertia and can therefore actively counteract fast vibrations up to the kHz range.

For example, it is possible that a first beam deflection unit deflects the electron beam to perform the electron beam-induced manipulation or perform imaging; a second beam deflection unit is controlled to compensate for disturbances. Thus, the first beam deflection unit can be dedicated to the electron beam induced manipulation or imaging, while the second beam deflection unit is dedicated to the electron beam induced disturbance compensation. For example, the first beam deflection unit can be located upstream or downstream along the electron beam from the second beam deflection unit. The first beam deflection unit is configured to apply a first beam deflection to the electron beam, and the second beam deflection unit is configured to apply a second beam deflection to the electron beam. The resulting sum deflection can then be a superposition of the first deflection and the second deflection. By providing dedicated beam deflection units for imaging or manipulation on the one hand and compensation on the other hand, the control of the beam deflection units can be simplified.

In addition, the hardware of the first and second beam deflection units can be adapted to the respective task.

If multiple beam deflection units are available, they may differ in operating bandwidth. In other words, if multiple beam deflection units are available, they may be relatively fast or relatively slow at deflecting a beam of charged particles. For example, a magnetostatic beam deflection unit may have an operating bandwidth in the range of kilohertz to tens of kilohertz. Accordingly, a magnetostatic beam deflection unit may be comparatively slow. Typically, such a magnetostatic beam deflection unit may be used for imaging a sample. This is because relatively long dwell times are required anyway, so it is not necessary to scan the charged particle beam particularly fast. On the other hand, an electrostatic beam deflection unit can have a relatively large operating bandwidth of MHz to tens of MHz. Thus, the operating bandwidth of the electrostatic beam deflection unit is larger than the operating bandwidth of the magnetostatic beam deflection unit. Typically, the electrostatic beam deflection unit is used for manipulation tasks because relatively small doses of charged particle exposure are required.

If multiple beam deflection units are available, they may differ in their deflection range. The deflection range indicates the maximum beam deflection that can be applied. For example, a magnetostatic beam deflection unit may have a comparatively large deflection range, while an electrostatic beam deflection unit may have a comparatively small deflection range.

A charged particle beam device is disclosed which includes a beam source and multiple beam deflection units and a sample stage. Each of the multiple beam deflection units is configured to deflect a beam of charged particles. The charged particles originate from the beam source. The deflection is for positioning the beam on the stage. The charged particle beam device includes at least one sensor. The at least one sensor is configured to measure at least one disturbance of at least one physical quantity. Each of the at least one physical quantity affects a beam offset of the beam on the stage. The charged particle beam device also includes at least one control unit. The at least one control unit is configured to determine one or more compensation signals to counteract the beam offset based on a sensor output of the at least one sensor. The at least one control unit is configured to provide control signals to the beam source and a first one of the plurality of beam deflection units to implement imaging of the sample mounted on the sample stage. The at least one control unit is further configured to provide, during imaging, the one or more compensation signals to a second one of the multiple beam deflection units.

For example, the first one of the multiple beam deflection units is a magnetostatic beam deflection unit; the second one of the multiple beam deflection units may be an electrostatic beam deflection unit.

The first one of the multiple beam deflection units may have a first operating bandwidth, while the second one of the multiple beam deflection units may have a second operating bandwidth, wherein the second operating bandwidth may be larger than the first operating bandwidth. In other words, it is possible to use a relatively slow magnetostatic beam deflection unit for imaging and a relatively fast electrostatic beam deflection unit for compensation.

A method of imaging a sample mounted on a sample stage of a charged particle beam device is disclosed. The charged particle beam device includes a beam source, multiple beam deflection units, and the sample stage. Each of the multiple beam deflection units is configured to deflect a beam of charged particles originating from the beam source to thereby position the beam on the sample stage. The method includes providing control signals to a first one of the multiple beam deflection units to thereby implement imaging of the sample. The method also includes obtaining a sensor output from one or more sensors of the charged particle beam apparatus. The one or more sensors measure one or more disturbances of one or more physical quantities, each of which affects a beam offset of the beam on the sample states. The method further includes determining one or more compensation signals for counteracting the beam based on the sensor output of the one or more sensors. The method further includes providing the one or more compensation signals to a second one of the multiple beam deflection units.

It is to be understood that the features mentioned above and those yet to be explained below may be used not only in the respective combinations indicated, but also in other combinations or in isolation without departing from the scope of the invention.

### BRIEF DESCRIPTION OF THE DRAWINGS

FIG. 1 schematically illustrates a placement offset of a charged particle beam according to various examples.

FIG. 2 schematically illustrates compensation of the placement offset of FIG. 1 according to various examples.

FIG. 3 schematically illustrates compensation of the placement offset of FIG. 1 according to various examples.

FIG. 4 schematically illustrates a focal offset of a charged particle beam and respective compensation according to various examples.

FIG. 5 schematically illustrates a focal offset and respective compensation according to various examples.

FIG. 6 schematically illustrates a charged particle beam device according to various examples.

FIG. 7 is a flowchart of a method according to various examples.

FIG. 8 is a flowchart of a method according to various examples.

FIG. 9 schematically illustrates a time series data of a sensor output and a characteristic fingerprint of a disturbance of a respective physical quantity according to various examples.

FIG. 10 is a flowchart of a method according to various examples.

FIG. 11 schematically illustrates an implementation of a charged particle beam device by a repair device according to various examples.

FIG. 12 schematically illustrates sensor placement with respect to the repair device of FIG. 11 according to various examples.

FIG. 13 schematically illustrates sensor placement in a repair device according to FIG. 11 according to various examples.

FIG. 14 schematically illustrates a defect of a lithography mask according to various examples.

FIG. 15 schematically illustrates a repaired defect of the lithography masks according to various examples.

FIG. 16 schematically illustrates a charged particle beam device according to various examples.

FIG. 17 schematically illustrates a charged particle beam device according to various examples.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the invention will be described in detail with reference to the accompanying drawings. It is to be understood that the following description of embodiments is not to be taken in a limiting sense. The scope of the invention is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Hereinafter, techniques associated with particle beam devices are disclosed. Specifically, techniques associated with charged particle beam devices are disclosed. Charged particles that can be used by such devices are electrons and/or ions. In other examples, non-charged particles may be used, e.g., photons. However, hereinafter, techniques will be disclosed in the context of charged particle beam devices, for illustrative purposes.

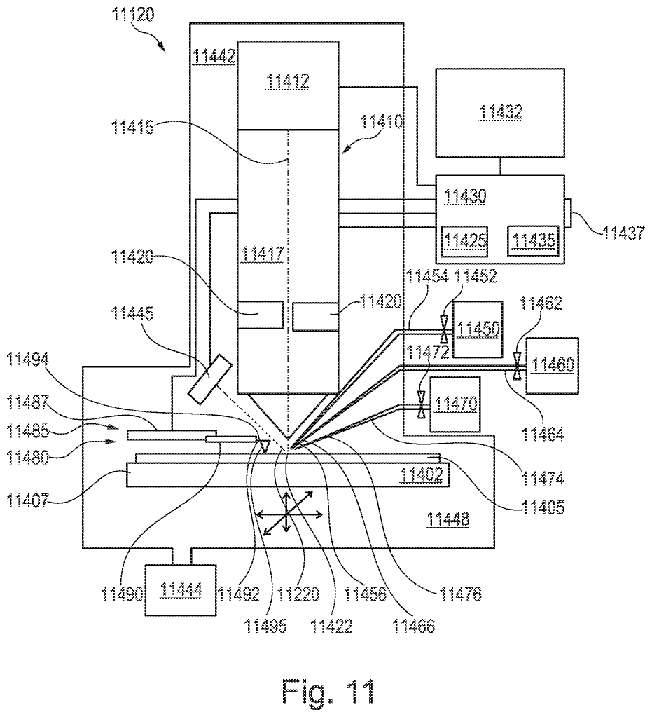

Examples of charged particle beam devices include: SEMs; Aberration Corrected SEMs (which typically have a comparatively larger detector aperture so that the depth range of the focus is small); FIB devices; multi-SEMs; cross-beam devices including a SEM and a FIB optics; and SEM or FIB with a precursor gas source, for repair/circuit edit tasks in a manipulation mode (also referred to as repair device; as will be explained in further detail in connection with FIG. 11 below).

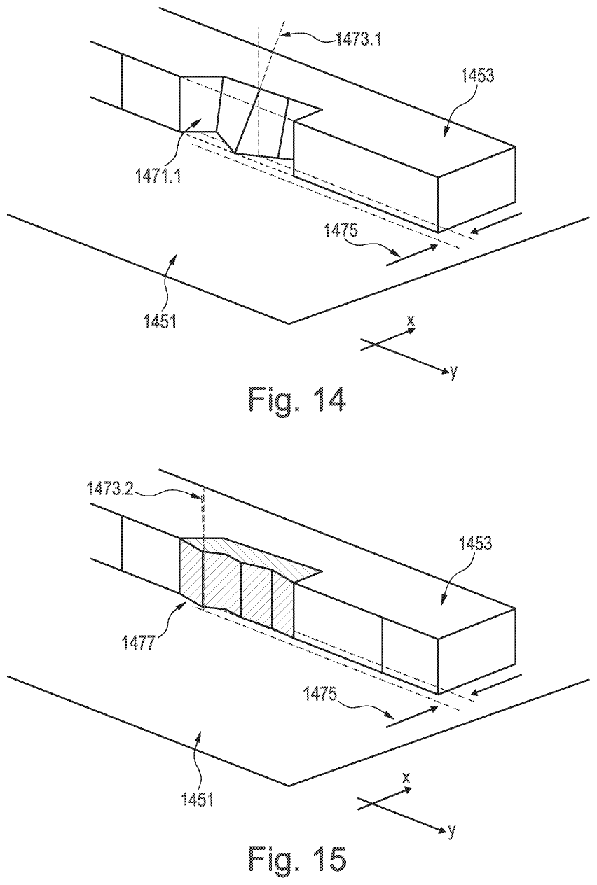

Repair tasks pertain to modifying structures on semiconductor masks that are used for lithography. Repair tasks are implemented using an electron beam-induced manipulation of a sample based on interaction of a precursor gas or gases with electron beams. Alternatively or additionally, ions can be used for repair or edit tasks. In some examples, repair tasks are employed for modifying semiconductor devices, e.g., electric circuits on wafers. In detail, charged particles—e.g., electrons or ions such as helium or neon—are used to modify such structures. For instance, the charged particle beam interacts with a precursor gas or precursor gases that are selectively supplied towards the sample stage. Then, one or more components of the precursor gas or gases is deposited onto the structure. It is also possible in examples to remove material using, e.g., a focused ion beam. A repair task is generally associated with a manipulation mode of a charged particle beam device where the sample/specimen is manipulated. To give a specific example, in photomask repair task using low-energy electron beams (200 V-2 kV), structural accuracies in the nm range are to be resolved and repaired (deposition processes and etching processes). For this purpose, it is particularly important that the stage (sample) is stationary and that there is no disturbing relative movement between the stage (sample) and the electron beam. Such relative movement can be caused by external disturbances such as acoustic influences, electromagnetic and mechanical vibrations. In particular, vibrations of the stage, which in our case are detected by a Michelson interferometer, lead to a relative movement of the stage and electron beam and thus impair the repair accuracy (minimum repair accuracy). A repair task, as a general rule, includes execution of control of a beam source, beam deflection unit and a precursor gas source using respective control signals to thereby implement an electron beam-induced manipulation of the sample. Examples of the manipulation are: electron-beam induced deposition (EBID) and electron-beam induced etching (EBIE). An example repair task will be explained later on in greater detail in connection with FIG. 14 and FIG. 15.

Various techniques disclosed herein are based on the finding that with ongoing reduction of typical dimensions of the investigated or modified structures (typically, structures are characterized by a critical dimension that marks the minimum structure size that needs to be handled) the requirements on accuracy for the operation of charged particle beam devices is increased. For instance, typical critical dimensions can be at less than 7 nanometers or even less than 5 nanometers.

Hereinafter, techniques are disclosed that facilitate operation of charged particle beam devices in inspection mode and/or manipulation mode at a high accuracy, to be able to handle structures having small critical dimensions, e.g., critical dimensions below 7 nanometers or even below 5 nanometers.

This is achieved by providing one or more compensation signals that compensate a beam offset. Details with respect to such beam offset and an associated compensation are disclosed in connection with the following FIGs.

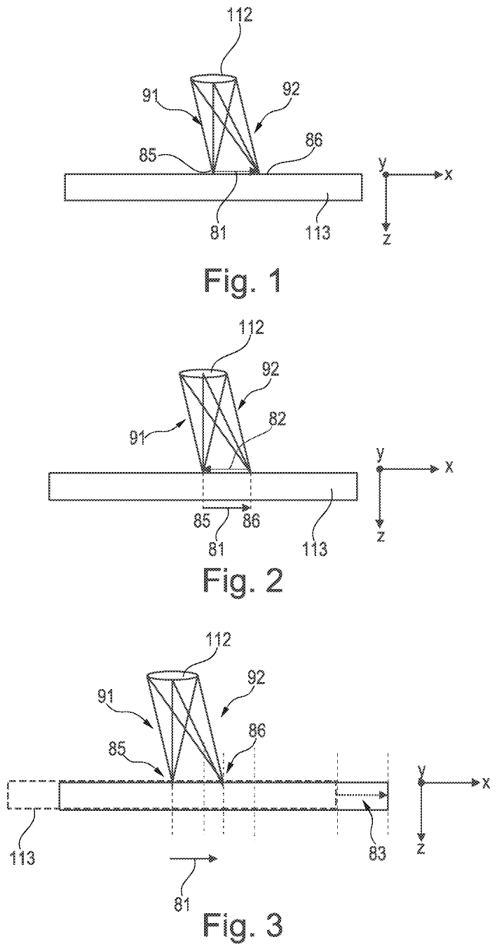

FIG. 1 schematically shows a charged particle beam 91—e.g., an electron or ion beam, e.g., of Helium ions—of a charged particle beam device. The charged particle beam 91 is focused, by an optics of a beam deflection unit 112, onto a certain position 85 on a sample stage 113 of the charged particle beam device. However, due to one or more disturbances, a beam offset, here specifically a placement offset 81, occurs, that displaces the charged particle beam 91 towards another position 86 on the sample stage 113. This is a displacement along x-direction. Likewise, a displacement along y-direction would be possible. Further, beyond such placement offset 81, disturbances can also introduce other aberrations that lead to a reduced accuracy.

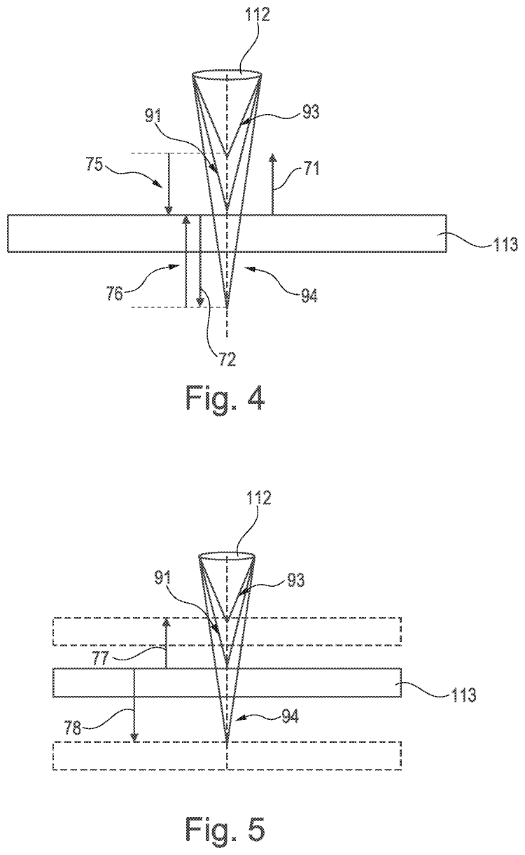

As a general rule, an accuracy of charged particle beam devices depends on, both, a resolution of the charged particle beam, as well as a placement of the charged particle beam on the sample stage. Typical resolutions are defined by a beam diameter that is typically in the range of 3 to 5 nanometers or even below (below 1 nm for aberration corrected instruments). On the other hand, the placement of the charged particle beam on the sample stage is typically affected by multiple disturbances of multiple physical quantities that affect the beam offset including the placement offset as described in connection with FIG. 1 above. A further type of beam offset is the focal offset, that will be explained in connection with FIG. 4 and FIG. 5 later on.

Such quite random placement offset reducing the accuracy of the beam placement is particularly critical for the operation of the charged particle beam device, because the specification requirements imposed on the accuracy of the placement of the charged particle beam on the sample stage are often even higher than the specification requirements imposed on the beam diameter/resolution. One reason for this is that, e.g., in connection with a manipulation mode, certain structures are required to be generated or edited as an accuracy of less than 3 nanometers, optionally less than 2 nanometers or even less than 1 nanometer. Further, while a placement offset while operating in the inspection mode may reduce the overall image quality of the acquired image, a placement offset due to disturbances during manipulation can lead to damage of expensive semiconductor structures or even lithography masks.

Accordingly, techniques are disclosed that facilitate compensating placement offsets as well as focal offsets by providing one or more compensation signals while the charged particle beam device operates in the manipulation mode.

According to various examples, a charged particle beam device includes multiple sensors for measuring multiple disturbances of multiple physical quantities. These multiple physical quantities all affect a beam offset of the beam on the sample stage. The charged particle beam device also includes a control unit that is configured to determine, based on a sensor output of the multiple sensors, one or more compensation signals to counteract the beam offset. The control unit is configured to provide the one or more compensation signals to at least one of a beam source of the charged particle beam device, a beam deflection unit of the charged particle beam device, the sample stage or one or more compensator modules.

As a general rule, the beam offset can include at least one of a placement offset (in FIG. 1 along the X direction or the Y direction, i.e., along the plane of the sample stage 113) or a focal offset (in FIG. 1 along the Z direction; perpendicular to the plane of the sample stage 113) of the beam.

By considering disturbances originating from multiple physical quantities, a comprehensive compensation of the beam offset is achieved. Specifically, more accurate compensation is achieved if compared to scenarios as known from the prior art according to which only individual physical quantities such as temperature, pressure, vibrations, or acoustic vibrations (i.e., sound waves) are considered in isolation. Cross-correlations between different pairs of physical quantities can be considered, to thereby more accurately perform the compensation of the beam offset. For instance, nonlinear effects due to cross correlations could be considered.

As a general rule, according to examples various physical quantities for compensation are considered. The multiple physical quantities are selected from the group including: acoustic vibration; vibration; pressure; humidity; laminar air flow; turbulent air flow; a differential quantity; temperature; a change rate (i.e., defining a change rate over time); a differential quantity; a vector quantity (e.g., electric field, magnetic field); or a scalar quantity (e.g., temperature, pressure).

A differential quantity describes a spatial gradient of a respective quantity, e.g., a temperature gradient or a pressure gradient. Oftentimes such differential quantities can exert stress or strain onto material, thereby causing a disturbance. Further examples include laminar or turbulent air flow.

Acoustic vibrations include, in some examples, external acoustic vibrations, e.g., stemming from objects moved about in the surrounding of the charged particle beam device. Passive damping systems are known in the prior art that attempt to decouple the charged particle beam device from its surrounding. However, such passive damping cannot usually absorb all acoustic vibrations so that active compensation, as described herein, can be desirable. Acoustic vibrations can have residual components of movable parts within the charged particle beam device. Such internal components can be excited by external acoustic vibrations via mechanical contacts, e.g., via the floor or support lines; or via sound.

Pressure varies as a function of time in some examples. Pressure variation can occur on a comparatively long time scale if compared to, e.g., acoustical vibrations. Passive compensation is known by pressure stabilization systems; however, such passive compensation has certain limitations in the accuracy. Pressure variation can occur for cooling liquid or ambient air. Ambient air pressure variation varies forces exerted on a vacuum housing of the charged particle beam device, leading to changes in the hardware arrangement.

Temperature variations are, to some extent, compensated, according to some examples, by passive temperature control, e.g., using stabilizing temperature reservoirs or external air conditioning system. Using active control according to the techniques disclosed herein can more accurately compensate disturbances of even small temperature variations. For instance, temperature variation of a cooling liquid is measured, according to various examples, using an appropriately placed temperature sensor. The temperature of a cooling liquid is measured in further examples. Temperature variation of electronic control devices or measurement devices is measured and compensated for in yet further examples. A temperature differential/gradient between two or more parts of the charged particle beam device is measured according to examples. For instance, temperature gradient between different measurement points in a fluid flow, e.g., a cooling liquid, is measured and the respective disturbance is compensated.

Another physical quality that can cause disturbances pertains is the electric field. Prior art systems often employ a respective shielding. However, while such shielding may to some extent be effective against external electric fields, internally generated electric fields, e.g., due to current or induced currents or charging of capacitances may not be easily shielded using an external shielding. Charging of unwanted particles inside the column by the charged particle beam can occur. On the other hand, using the techniques described herein, sensors close to the optics are used in some examples, e.g., inside the vacuum chamber of the charged particle beam device, to measure the electrical field and then compensate for such electrical fields. Similar observations also apply to magnetic fields.

As will be appreciated from the above, some of the disturbances—e.g., magnetic or electric field—have a direct impact on to the charged particle beam, by deflecting the charged particles that propagate along the beam. For instance, an electric field or a magnetic field exerts a force on electrons or ions to deflect these particles. These are direct disturbances. Disturbances can also have an indirect impact on to the charged particle beam by impacting one or more parts of the charged particle beam device. For instance, acoustic vibrations cause a positional offset of optics of a beam deflection unit of the charged particle beam device and this positional offset then causes the beam offset of the beam. Electric or magnetic fields change analog supply currents or voltages of the beam source or optics of the beam deflection unit of the charged particle beam device; this then, in turn, affects the placement offset. These are indirect disturbances. According to the techniques disclosed herein, it is possible to compensate for direct disturbances as well as indirect disturbances.

For instance, placement offsets as illustrated in FIG. 1, or, more generally, beam offsets can occur in an imaging mode of a scanning electron microscope. For instance, movement of magnetic materials such as iron, cobalt, nickel, steel, etc. can change the magnetic field at the site of the charged particle beam. This can be caused by movement in the surrounding of the charged particle beam device, e.g., due to elevators, cranes, doors, lifting trucks, moving persons, cell phones, keys, etc.

Similar considerations also apply to focused ion beam devices. Using the focused ion beams, it is possible to remove material, in a manipulation mode, from a sample. In case of disturbances affecting the ion beam, the material is removed at unintended regions of the sample. Thus, using the techniques disclosed herein, the ion beam is stabilized on the sample and sample stage, respectively. This helps to avoid damage to the sample and allows for higher accuracy, e.g., in the preparation of transmission electron microscope lamellas or 3D tomographic sample investigation.

Similarly, for mask repair processes in a manipulation task, structures on the lithography mask are repaired by depositing material using an electron or ion beam induced process; and/or removing material locally from the lithography mask. By using the techniques disclosed herein, any beam offsets of the electron or ion beam with respect to the lithography mask and sample stage, respectively, are reduced so that a higher accuracy in the manipulation task is achieved.

As a general rule, various options are available for counteracting the beam offset according to the disclosed examples. According to examples, different options of counteracting the beam offset are employed for different root causes of the disturbances. For example, different options for counteracting the beam offset are employed for direct and indirect disturbances, as explained above, respectively. For example, a compensation signal is applied to optics of the beam deflection unit, to steer the beam into an opposing direction if compared to the placement offset. For example, a compensation signal is applied to a focusing optics of the beam deflection unit to change the focal length, to counteract a focal offset caused by a respective disturbance. In some examples, the sample stage is—alternatively or additionally—controlled to reposition to counteract a beam offset. In still further examples, dedicated compensation is used for, e.g., external coils for applying magnetic fields or electric field plates for applying electric fields. For instance, compensation of DC magnetic fields or slowly varying magnetic fields is achieved using Helmholtz coil pairs, one coil pair for each spatial direction. Such coil pairs are positioned outside of the housing of the charged particle beam device. Active cooling or heating is used according to further example. For example, a heating or cooling element is provided in thermal contact with a cooling liquid and active temperature control is possible. In some examples, active damping for suppressing vibrations is controlled. In some examples, pressure is actively controlled. Hereinafter, devices or units that indirectly counteract the beam offset—i.e., that do not directly exert a force onto the charged particle beam by applying a magnetic or electric field or that do not shift the sample stage with respect to the charged particle beam—are referred to as compensator modules. Such compensator modules are controlled by respective compensation signals.

Hereinafter, techniques are primarily explained in connection with applying compensation signals to the beam deflection unit and/or the sample stage. Some example options for counteracting the beam offset by such means are explained next.

FIG. 2 illustrates aspects with respect to counteracting the placement offset 81 of FIG. 1. As illustrated in FIG. 2, an additional beam shift 82 that counteracts the placement offset 81 is achieved by providing a control signal to the beam deflection unit 112. For example, an additional voltage is applied to a respective electronic lens.

FIG. 3 schematically illustrates counteracting the placement offset 81 of FIG. 1. In the scenario of FIG. 3, a compensation signal is applied to a control motor of the sample stage 113, so as to effect a stage shift 83 that counteracts the placement offset 81.

Such techniques as illustrated in FIG. 3 may be particularly helpful for closed-loop controlled motorized stages 113. For instance, interferometric stages are known for which a positioning accuracy in the nanometer regime is obtained.

Above, scenarios of a placement offset that is affected by multiple disturbances have been disclosed. Alternatively or additionally to affecting the placement offset, disturbances can affect a focal offset of the charged particle beam. This is illustrated in FIG. 4.

In FIG. 4, the unaffected beam 91 in absence of any disturbances is illustrated. Furthermore, two disturbed beams 93, 94 subject to a respective focal offset 71, 72 are illustrated. It is possible to counteract the focal offset 71, 72 by applying an additional defocus to the beam. The beam deflection unit 112 can be controlled accordingly. The defocus 75 to counteract the focal offset 71 is illustrated, as well as the defocus 76 to counteract the focal offset 72 is illustrated. In an alternative scenario, as illustrated in FIG. 5, it is also possible to apply respective vertical stage shifts 77, 78.

According to various examples, the compensation of a focal offset is applied to aberration-corrected SEMs. Typically, aberration-corrected SEMs have a comparatively large numerical aperture, therefore having a shallow focal depth range. Such aberration-corrected SEMs can be employed for manipulation tasks and it is possible that the thickness of structures to be manipulated is in the same range or even smaller than the focal depth range. In such scenarios, compensation of the focal offset is particularly important to achieve good results of the manipulation task.

Various techniques are based on the finding that disturbances can occur on different time scales. On the one hand, there can be slowly varying disturbances caused by, e.g., DC magnetic fields, temperature, or pressure changes. Typically, such slowly varying disturbances can be compensated using techniques as disclosed herein, e.g., by applying one or more compensation signals to counteract the beam offset. Here, using a compensation by applying additional voltages to beam optics—cf. FIG. 2 or FIG. 4—typically provides for a shorter response time if compared to providing compensation based on stage shifts—cf. FIG. 3 and FIG. 5. This is because movement of the stage typically requires longer time durations, due to limited movement speed of the motor. The operation of the charged particle beam device, e.g., an imaging mode or manipulation mode, does not have to be stopped for such compensation, i.e., the compensation can be applied during ongoing operation.

On the other hand, some disturbances can be varying on a fast time scale, e.g., within seconds or even in the sub-second regime. Examples pertain to physical quantities such as acoustic or seismic vibrations, e.g., due to oscillation of the building foundation. To also compensate for such fast disturbances, techniques will be disclosed hereinafter that enable to determine a predictive component of the beam offset. Alternatively or additionally, information regarding such disturbances is stored in further examples, such information being determined based on the sensor output, e.g., along with imaging data acquired in an imaging mode. In other words, according to examples, based on the sensor output of multiple sensors, meta data is determined that is indicative of one or more compensation operations to counteract the beam offset in image data that is acquired by the charged particle beam device that operates in the imaging mode and then the meta data is stored in association with the image data. Then, acquired image data is digitally post-processed to compensate, after acquisition, for such disturbances based on the meta data.

In some examples, disturbances are detected that lead to suspending operation of the charged particle beam device. E.g., the charged particle beam can be blanked. The imaging mode or manipulation mode is interrupted, until the disturbance has resolved. Such a scenario is, in particular, helpful during manipulation mode; to avoid damage to the manipulated specimen.

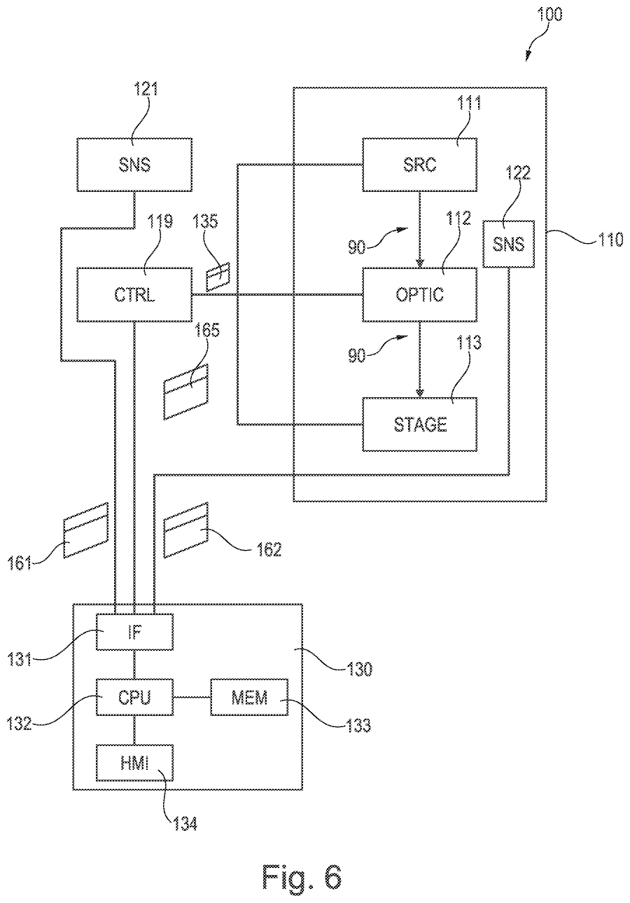

FIG. 6 schematically illustrates a charged particle beam device 100 according to various examples. For example, the charged particle beam device 100 could be a charged particle beam repair device. The charged particle beam device 100 includes a vacuum chamber 110. A beam source 111, a beam deflection unit 112 (as a general rule, multiple beam deflection units may be used, e.g., a first one for imaging and/or manipulation, and a second one for compensation of disturbances) and a sample stage 113 are arranged inside the vacuum chamber 110. An embedded control unit 119 controls the beam source 111, the beam deflection unit 112, and the sample stage 113. The control unit 119 can also control further parts of the charged particle beam device 100, e.g., a control valve of a precursor gas source (not shown in FIG. 6).

The control unit 119 may be implemented in hardware and/or software. For instance, the control unit 119 may include a proportional control module, e.g., implemented in hardware. The proportional control module can be part of a closed control loop for compensating disturbances and implement a proportional calculation of a compensation signal based on one or more sensor signals. The proportional control module can determine a compensation signal based on an input signal multiplied by a gain and summed with an offset. The proportional control module can be a proportional-integral (PI) control module, a proportional derivative (PD) control module, a proportional-integral-derivative (PID) or a proportional-latency (PT) control module.

Also illustrated are two sensors 121, 122 for measuring disturbances of physical quantities that each affect a beam offset of the charged particle beam 90 on the sample stage 113.

While in the scenario FIG. 6 two sensors 121, 122 are illustrated, as a general rule, only a single sensor is used or more than two sensors are used.

In some examples, at least one of multiple sensors is arranged inside the vacuum chamber 110. Alternatively or additionally, at least one sensor is arranged outside of the vacuum chamber 110.

For example, sensors measuring the same physical quantity, e.g., temperature, are located at multiple positions. Thereby, a differential physical quantity is measured, e.g., a temperature or pressure differential.

By arranging sensors outside of the vacuum chamber, it is possible to measure physical quantities that slowly vary as a function of position, e.g., external electric fields or external magnetic fields. At the same time, an impact on the particle beam by operating the sensor can be avoided. In some examples, a sensor is nonetheless placed closer to the beam path of the beam 90, e.g., for physical quantities that show a strong positional dependency.

Also illustrated is a control unit 130. In some examples, the control unit 130 is implemented by a computer. The control unit 130 communicates with the embedded control unit 119, as well as the sensors 121, 122. While in FIG. 6 a scenario is illustrated according to which the control unit 130 communicates directly with the sensors 121, 122, such communication in other examples is via the embedded control unit 119.

In any case, the control unit 130 obtains sensor signals 161, 162 (i.e., sensor output) from the sensors 121, 122. Based on this, the control unit 130 provides one or more compensation signals 165 to one or more parts of the charged particle beam device 100, to counteract the placement offset.

The control unit 130 includes a processor 132 that is coupled to a memory 133. The processor 132 also communicates via the communication interface 131. The processor loads program code from the memory 133 and executes the program code. Upon executing the program code, the processor 132 performs techniques as disclosed herein with respect to compensating multiple disturbances of multiple physical quantities that each affect a beam offset.

The control unit 130 also includes a human machine interface (HMI) 134, e.g., a display, a web interface, a mouse, a keyboard, etc. User input is received via the HMI 134 or information is output via the HMI 134. For instance, an indication of a site-specific disturbance event is obtained from the user via the HMI 134. In some examples, a warning is output to the user via the HMI 134.

While hereinafter scenarios are disclosed which pertain to logic associated with the beam offset compensation residing at the control unit 130, in other examples at least parts of that logic reside at the embedded control unit 119.

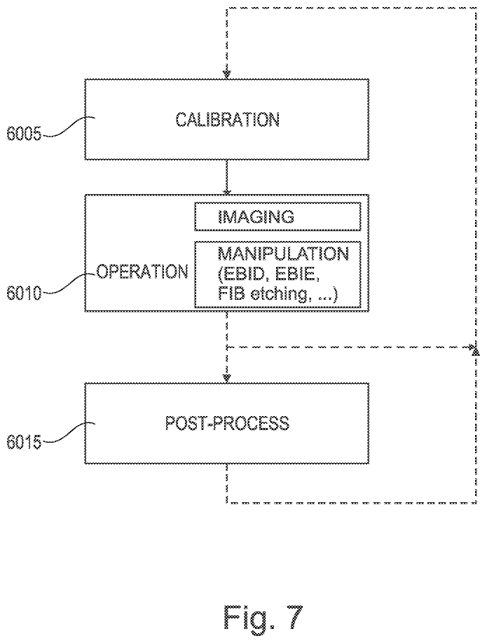

FIG. 7 is a flowchart of a method according to various examples. FIG. 7 illustrates multiple phases of operation of a charged particle beam device such as the charged particle beam device 100 of FIG. 6. The method of FIG. 7 may be executed by the control unit 130 and/or the embedded control unit 119.

Box 6005 corresponds to a calibration phase. During the calibration phase, one or more transfer functions are set up between sensor outputs of multiple sensors measuring disturbances of multiple physical quantities and compensation signals. Training data for training a machine-learning algorithm can be acquired.

Such transfer functions, accordingly, link values of multiple physical quantities (represented by the sensor signals 161, 162) to beam offset compensations (represented by the compensation signal 165).

Box 6010 then corresponds to an operation phase. During the operation phase, the charged particle beam device operates in an imaging mode or a manipulation mode. For instance, as part of the imaging mode, a control unit of the charged particle beam device can provide, to a beam source and a beam deflection unit of the charged particle beam device, control signals to implement imaging of a sample mounted to a sample stage of the charged particle beam device. As part of the manipulation mode, the control unit of the charged particle beam device provides, to the beam source, the beam deflection unit, and a precursor gas source (e.g., including a gas reservoir or tank and a respective nozzle located close to the sample stage; details will be explained in connection with FIG. 11A) control signals to implement an electron-beam-induced manipulation of the sample mounted to the sample stage. Here, the precursor gas supply through the precursor gas source interacts with the electrons of the electron-beam. Material can be deposited or locally etched.

During the operation phase, compensation of multiple disturbances of multiple physical quantities is employed; the multiple physical quantities each affect a beam offset of the beam of the charged particle beam device with respect to the sample stage. For example, the control unit employs the transfer function obtained from box 6005 to determine, based on a sensor output of the multiple sensors, the one or more compensation signals to contact any beam offset and then provide the one or more compensation signals to one or more parts of the charged particle beam device.

Also illustrated in FIG. 7 is an optional post-processing phase, associated with box 6015. Here, meta data that is acquired based on the sensor output of multiple sensors is used to apply one or more compensation operations to counteract a beam offset by postprocessing respective image data. In some examples, such compensation operations include applying an imaging shift, e.g., displacing pixels of image is included in the image data by a certain image offset. Also, rotation operations or skew operations are used in further examples. In some examples, complex image artifacts are compensated. Examples of image artifacts include artificially reoccurring contrast. To compensate this, the compensation operations can be implemented using, e.g., a neural network that obtains configuration information in the form of the meta data.

As illustrated in FIG. 7 by the dashed line, it is possible to re-execute the calibration mode of box 6005 from time to time. Thereby, certain disturbance events that are site-specific, i.e., depend on the specific deployment side of the charged particle beam device, are captured. This will be explained in further detail later-on.

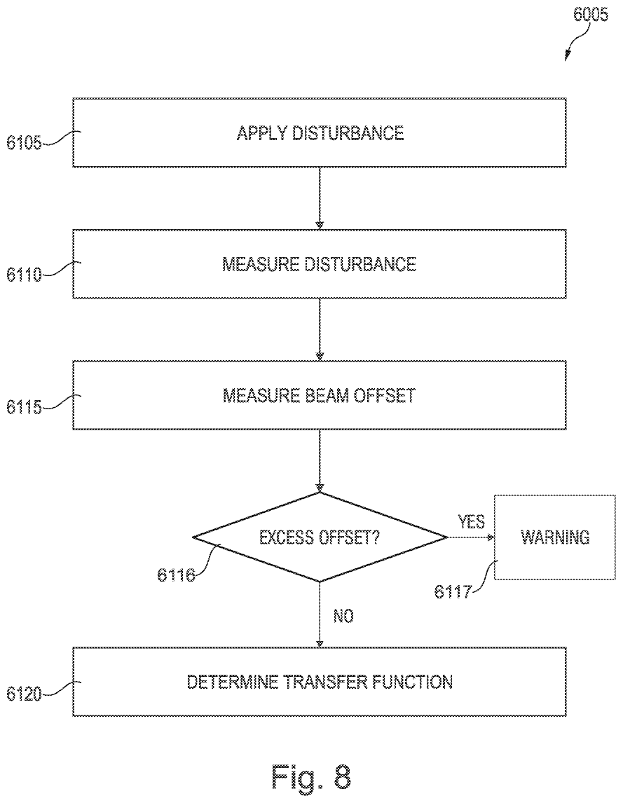

Next, details with respect to the calibration phase of box 6005 are disclosed in connection with FIG. 8.

FIG. 8 is a flowchart of a method according to various examples. FIG. 8 illustrates details with respect to the calibration phase of box 6005.

For example, a calibration phase of box 6005 can be re-executed from time to time, e.g., continuously. A calibration phase can be executed each time a repair task is scheduled. It would also be possible that the calibration phase is one that is executed by a manufacture of the charged particle beam repair device.

The calibration enables to determine multiple parameter values of a transfer function to adapt the transfer function to the real dynamic system. This can be done using known mathematical methods. Generally, a known disturbance is applied to the system and the response of the system is measured. The response of the system can be measured by capturing images of structures on a sample in rapid succession and determining the displacement of the imaged object as a function of time. The object can be a photomask or a sample that is installed in the system specifically for this purpose. The measured values of the sensors are recorded at the same time as the image is captured, so that a temporal correlation with the displacement is possible.

Initially, at box 6105, one or more disturbances are applied; this is done by modifying one or more physical quantities. Some examples are: apply a certain disturbing electrical or magnetic field (e.g., using a Helmholtz coil setup surrounding the charged particle beam device), vary the surrounding temperature (e.g., in a temperature-stabilized environment), vary the surrounding pressure, etc. where the one or more disturbances are actively applied, the respective magnitude of the disturbance is known.

As will be appreciated from the above, a “tailored” disturbance event is thus triggered, for calibration purposes.

As a general rule, a disturbance applied at box 6105 can come from different sources: From “naturally” occurring sources of interference in the system's environment (background noise, ground vibrations, electromagnetic radiation, etc.). From actuators that are either used for calibration purposes or are permanently attached to the system. Examples include loudspeakers, shakers, antennas, etc.

As a general rule, such active application of a certain disturbance is optional. In other scenarios, at box 6110 naturally-occurring disturbances are measured, e.g., site-specific to disturbances. In other words, in some scenarios, a disturbance event is actively triggered at box 6105; while in other scenarios, environmental disturbance events are monitored and characterized at box 6110.

Then, at box 6115, it is possible to measure the beam offset.

This beam offset can either result from a respective tailored disturbance that is actively applied at box 6105; the beam offset can alternatively result from a natively occurring disturbance, e.g., from environmental disturbance events. For example, a response of the system can be measured by capturing images of structures on a sample in rapid succession and determining the displacement of the imaged object as a function of time. For example, a placement offset and/or a focal offset of the beam is measured. This can be achieved using, e.g., a test pattern sample and using a respective inspection task. For instance, an image of the test pattern acquired by the charged particle device operating in the imaging mode while the disturbance is present is compared with a ground truth knowledge regarding the test pattern. From deviations between the image appearance of the test pattern and the ground truth regarding the test pattern, a conclusion on the beam offset is drawn. For instance, image shifts could be determined between a true position of certain features of the test pattern and a position at which those features are depicted in the image. For instance, an image blur could be quantified to determine the focal offset. For instance, marker structures (e.g., drift markers or alignment markers) attached to the sample (e.g., the same sample for which a repair task is scheduled) for which a ground truth regarding position and/or relative alignment is known, may be used. An appearance of the marker structures can be determined from the images acquired using charged particle imaging; and a difference between this appearance and the ground truth can be determined. This difference can be used to determine the beam offset. At box 6116, it is possible to determine whether the beam offset measured at box 6115 exceeds a certain threshold, i.e., is excessively large. In the affirmative, it would be possible to execute box 6117. Here, a warning or error message can be output. A fault mode may be activated. Else, at box 6120, a transfer function between the disturbance and the beam offset is determined. This transfer function is then stored for later use during the compensation mode (cf. FIG. 7: box 6010).

Next, various examples of determining the transfer function at box 6120 will be discussed.

In one example, the one or more compensation signals are determined using a look-up table that links the sensor output with one or more compensation signals. In other words, for multiple strengths of the disturbances, e.g., multiple values of the respective physical quantities, an associated beam offset and the required compensation signals to compensate therefore are determined. Respective value pairs are then stored in the look-up table. Linear interpolation is optionally used during the operation phase to increase the accuracy.

The look-up table can be device-specific, i.e., different charged particle beam devices can have different look-up tables. Site-specific disturbances can be used to populate such device-specific look-up tables. The look-up table could also be stored in the cloud, and thus be retrieved via the Internet. This allows to centrally maintain and manage disturbance compensation for multiple charged particle beam devices.

An example look-up table is provided by TAB. 1 below:

TABLE 1
example lookup table that links a temperature disturbance
within offset voltage to be applied at beam optics of
a beam deflection unit of the charged particle device.

| TEMPERATURE DISTURBANCE | OFFSET VOLTAGE |
|---|---|
| +0.2 K | +0.3 V |
| +0.4 K | +0.58 V |
| +0.6 K | +0.88 V |

Such lookup table has the advantage that it is not required to model dependencies between the sensor output and the compensation signal using predetermined functions. Nonlinear dependencies are directly captured. On the other hand, such lookup table can have a significant size. This can lead to latency in the lookup of the appropriate compensation signal, which can be a problem, in particular, for quickly varying disturbances.

In another example, the one or more compensation signals are determined using a (pre-parameterized) functional dependency.

Such functional dependency is illustrated for a linear case. A linear functional dependency can be implemented using a proportional control module (e.g., a PI, PD, PID, or PT control module) of the control unit. For instance, for a scalar physical quantity, e.g., temperature, such linear functional dependency may be defined as follows:

$$( \begin{matrix}{P}_{x} \\ {P}_{y} \\ {P}_{z}\end{matrix} ) = ( \begin{matrix}{T}_{x}^{c} \\ {T}_{y}^{c} \\ {T}_{z}^{c}\end{matrix} ) Δ T ,$$

here ΔT denotes the temperature disturbance (e.g., defined with respect to a reference temperature) and is obtained from the sensor output, Pₓ denotes the x component of the compensation of the placement offset, P_{y} denotes the y component of the compensation of the placement offset, and P_{z} denotes the compensation of the focal offset. The linear (proportional) functional dependencies are then given by the parameters

$${T}_{x}^{c} , {T}_{y}^{c} , {T}_{z}^{c} .$$

These are determined during the calibration (pre-parameterization). The placement offset defines the one or more compensation signals.

For instance, for a vector physical quantity, e.g., electrical field, such linear functional dependency is defined as follows:

$$( \begin{matrix}{P}_{x} \\ {P}_{y} \\ {P}_{z}\end{matrix} ) = {E}^{c} ( \begin{matrix}Δ {E}_{x} \\ Δ {E}_{y} \\ Δ {E}_{z}\end{matrix} ) ,$$

where E^{c} is a 3×3 matrix wherein the matrix elements are determined during the calibration. ΔEₓ, ΔE_{y}, ΔE_{z} denote the components of the disturbing electric field. A linear combination of these measurement values ΔEₓ, ΔE_{y}, ΔE_{z} is calculated. In the scenario above, a given physical quantity—e.g., temperature, electric field, and so forth—has an impact on the beam offset. Impacts of different physical quantities onto the beam offset can superimpose. A linear or non-linear combination can be considered. This may also be referred to as multi-input multi-output (MIMO) transfer function. In some scenarios, it is possible to consider the different physical quantities independent of each other, i.e., neglect mixing effect between the impacts onto the beam offset of different physical quantities.

In some scenarios, cross-dependencies between multiple disturbances that are associated with different physical quantities are considered. A MIMO transfer function may be considered.

For instance, an example would be a cross-dependency between temperature and pressure, as explained below:

$$( \begin{matrix}{P}_{x} \\ {P}_{y} \\ {P}_{z}\end{matrix} ) = {X}^{c} ( \begin{matrix}Δ T \\ Δ p\end{matrix} ) ,$$

where the 2×3 matrix X^{c} has non-zero off-diagonal elements defining the cross-dependencies between pressure disturbance and temperature disturbance.

Above, linear functional dependencies have been disclosed, but it would be likewise possible to include non-linear terms, e.g., quadratic terms, cubic terms, etc.

Beyond such functional dependencies as exemplified above, in another example, the one or more compensation signals are determined using a model. For example, the compensation of the positioning and focal offset is determined using a trained neural network or another machine learning algorithm or generally a pre-trained algorithm. The trained neural network receives, as input, a vector including the sensor output of the multiple sensors, e.g., temperature, pressure, multiple components of the electrical field, multiple components of the magnetic field, etc. Then, the neural network outputs the one or more compensation signals or the beam offset from which the one or more compensation signals are determined. Such neural network is trained using ground truth labels acquired during the calibration mode, i.e., the measured beam offset of box 6115 in combination with input vectors as determined at box 6105 or at box 6110.

This is an example of a data-driven model. In other examples, also an analytical model may be employed. To give an example, a change in pressure has been shown to lead to a twist of the beam optics column. This results in a displacement of the focal point on a circle tilted with respect to the surface of the sample stage, i.e., the displacement has x and y and z components. A focal offset either in +z-direction or in −z-direction can occur. An analytical model is determined according to example, the analytical model determining torque exerted on the optics column based on the pressure gradient. Such analytical model has the benefit of reduced lead time in the parameterization, e.g., if compared to a lengthy calibration of a transfer function. Such model can be extended, in some examples, to also cover placement offsets based to other disturbances such as magnetic field.

Above, scenarios of instantaneous compensation of disturbances have been disclosed. Such techniques generally work well for slowly-varying disturbances, e.g., in the kHz regime or below. For fast-varying disturbances, an even higher accuracy can be achieved by considering time-resolved properties of the disturbances. This is explained in further detail below.

According to various examples, a predictive component of the beam offset is determined based on the sensor output of the multiple sensors and determine the one or more compensation signals based on the predictive component of the beam offset. In other words, the disturbances are anticipated for a certain look-ahead time duration.

Such techniques are based on the finding that certain disturbance events are repetitive. Specifically, site-specific disturbance events can re-occur over the course of time. For instance, stray magnetic fields can be caused by movement of an office chair between two desks in the laboratory or deployment site of the charged particle beam device. For instance, vibrations can be caused by a train entering or leaving a train station nearby or a delivery truck arriving at or leaving from a loading dock. In another example, stray magnetic fields can be caused by operation of equipment in a wafer fab, e.g., opening or closing of a load lock, depressurization of a vacuum chamber, or temperature changes as a function of daytime/sun height, etc. These are only some examples of typical repetitive disturbance events that are site-specific.

To make such predictions, in some examples, the sensor output of at least one of the multiple sensors includes respective time series data. In other words, sensor readings over a certain observation duration (e.g., along with respective timestamps) are considered. Then, the predictive component is determined based on an analysis of the time series data.

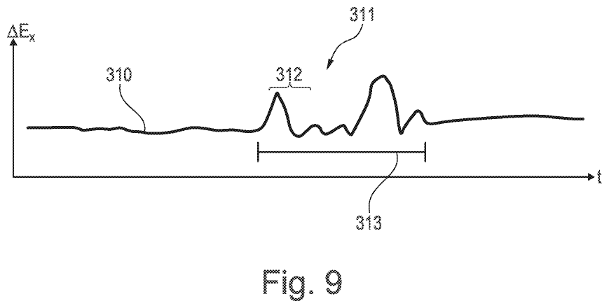

There are various options for performing such analysis of the time series data. In one option, fingerprints of one or more predetermined disturbance events are found in the time series data. These fingerprints include characteristic time dependencies of the sensor output of the respective at least one sensor. The fingerprints pertain to characteristic time-domain patterns. This is illustrated in connection with FIG. 9.

FIG. 9 illustrates—as an illustrative example—a disturbance of the x-component of the electrical field that affects the beam offset of the charged particle beam, over the course of time. The time series data 310 of the x-component of the electrical field is obtained from a respective electrical field sensor.

Illustrated is a disturbance event 311 that is caused, as one example, by arrival of a bus at the bus station nearby the deployment site of the charged particle beam device. A respective disturbance duration 313 is also illustrated. For instance, the disturbance duration 313 could be in the range of seconds or minutes.

The disturbance event 311 has a characteristic fingerprint 312 (here: large upswing then small downswing with respect to the average of the time series data 310 prior to the disturbance event) that is detected in the time series data of the electric field sensor. Once this fingerprint 312 has been found, a prediction on the future behavior of the disturbance can be made, i.e., a predictive component of the beam offset can be determined (under the assumption of a repetitive nature of the disturbance). The behavior of the disturbance during the remaining disturbance duration 313 can be predicted.

When operating in the calibration phase of box 6005 (cf. FIG. 7), a repository is populated, according to some examples, with fingerprints of multiple disturbance events. To find such fingerprints, various options are conceivable. In one option, repetitions of the fingerprints are identified. For instance, during the calibration mode, the sensor output of the respective at least one sensor is monitored over an extended duration, e.g., hours or days or even weeks and then find repetitions of the fingerprints. In a further option, user input data is obtained that is indicative of a respective one of the one or more disturbance events. For instance, referring to FIG. 9, a user labels/annotates the time series data to identify the disturbance duration 313. The user may do so with domain knowledge, e.g., in the discussed example the user may be aware of the arrival of the bus at the bus station. Another option includes training a predictive model based on the timeseries data that is measured during the calibration mode to find the fingerprints. Then, the predictive model, e.g., a recurrent neural network such as a long-short-term memory (LSTM) neural network, is enabled to determine the predictive component of the beam offset. This enables to react to disturbance events having a signal component with a high bandwidth. In other words, disturbance events with fast time dynamics, e.g., in the sub-millisecond regime or even in the microsecond regime can be compensated for. This is because once the fingerprint has been detected a compensation signal can be pro-actively played out.

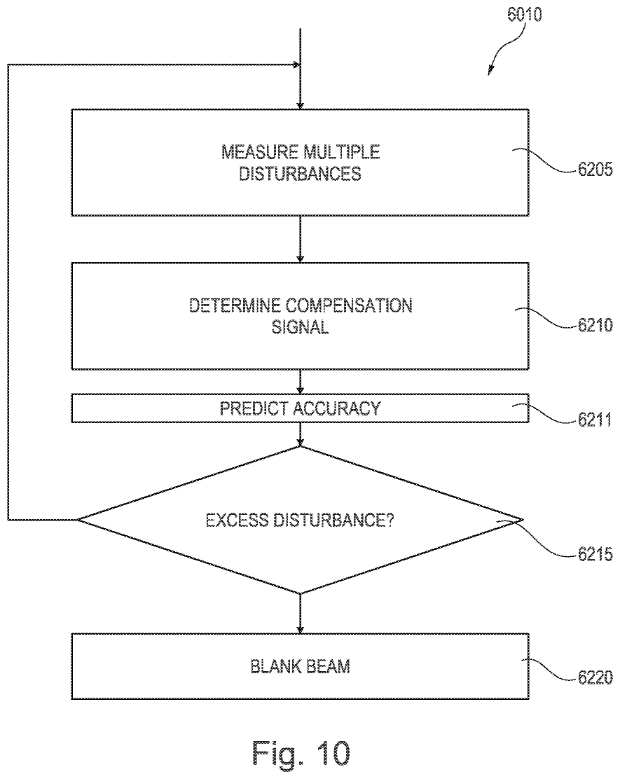

FIG. 10 is a flowchart of an example method. FIG. 10 schematically illustrates operation in the operation phase of box 6010 of FIG. 7.

At box 6205, multiple sensors of the charged particle beam device measure multiple disturbances of multiple physical quantities that each effect a beam offset, e.g., a placement offset and/or a focal offset, of the charged particle beam on a sample stage. A respective sensor output including multiple sensor signals provided by the multiple sensors is provided. The sensor output is indicative of the values of the physical quantities. I.e., the sensor output is associated with the disturbances. The disturbances can super-imposed or can correlate with each other.

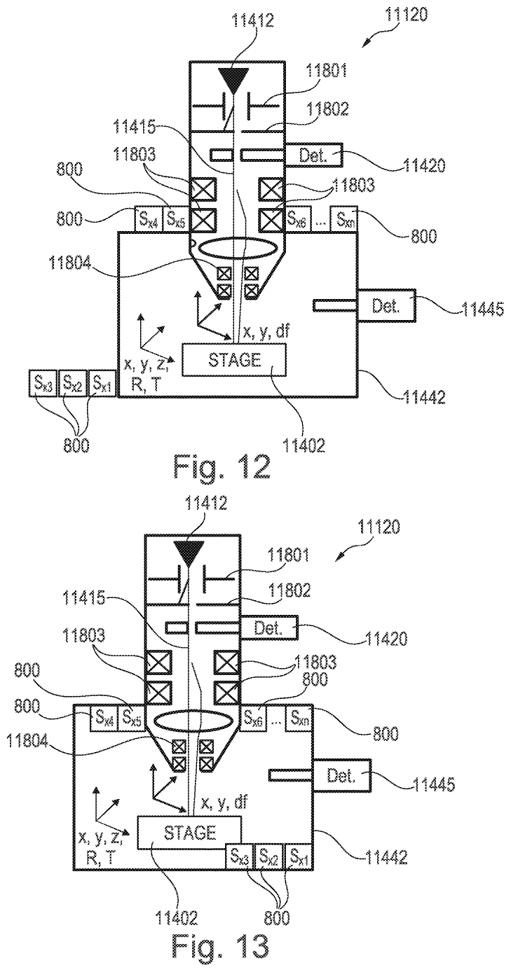

As a general rule, different placements for the multiple sensors are conceivable. Example placements will be discussed later on in connection with FIG. 12 in FIG. 13.

Next, at box 6210, one or more compensation signals are determined to counteract such beam offset. This is based on the sensor output of the multiple sensors. More specifically, the disturbances are estimated from the sensor output and the disturbances are translated into the one or more compensation signals.

The one or more compensation signals can be used for controlling a beam deflection unit. For instance, a beam deflection unit can be controlled that does not deflect the beam in an imaging or manipulation task. Rather, deflection of the beam for imaging or manipulation of a sample can be achieved by another, separate beam deflection unit.

Above, examples have been disclosed that facilitate determining such compensation signals, e.g., using a transfer function that may be implemented by a lookup table, a model—e.g., a data-driven model using machine learning or an analytical model —, a functional dependency, a machine-learning algorithm/model (e.g., a deep neural network), etc. Training data can be acquired in a calibration phase.

It is also possible to determine a predictive component of the beam offset, to thereby reduce a latency and applying the compensation signal and provide more accurate compensation.

In some scenarios, alternatively or additionally to determining compensation signals to actively compensate the beam offset during the operation of the charged particle beam device, e.g., in the imaging mode or the manipulation mode, meta data that is indicative of one or more compensation operations is determined, to counteract the beam offset in imaging data. This enables post-processing of the imaging data (cf. FIG. 7: box 6015). Here, compensation of the beam offset is achieved when digitally postprocessing imaging data that is acquired using the charged particle beam device; alternatively or additionally to compensation of at least a part of the beam offset during the operation.

A trust level of respective image data can be determined. A log file can be generated and maintained to store the disturbances or specifically the one or more compensation signals. Log file entries can be created in accordance with a schedule and/or event-triggered and/or continuously. It is possible to detect vibrations and other disturbances (magnetic fields, acoustic influences, etc. as disclosed above) using the multiple sensors in order to log and/or display the current health status of the system. This health status can be logged permanently (at regular time intervals or when one or more thresholds are exceeded).

At box 6211 is optionally possible to predict, based on the sensor output and/or the one or more compensation signals determined at box 6210, an accuracy of an operation of the charged particle beam device during a prediction time duration. This can equate to predicting the level of disturbances. For example, a recurrent neural network or an LSTM is used for making such prediction. Again, such prediction can be based on characteristic fingerprints of repetitive disturbance events, as discussed in connection with FIG. 9. Different to what has been explained in connection with FIG. 9, such prediction of the level of accuracy may not directly impact the compensation signals. Sometimes, the prediction may not be accurate enough to determine a predictive component of one or more compensation signals. In such a scenario, it is still possible to predict the accuracy. In some examples, such accuracy is output via an HMI to the user. The user may then decide whether to abort or not a port the operation. In other examples, the prediction of the accuracy is used in the context of box 6215.

Sometimes, a scenario occurs according to which the disturbance exceeds or is predicted to exceed (cf. box 6211) a certain predetermined threshold. If a disturbance exceeds a predetermined threshold, it is assumed that such disturbance cannot be compensated.

Accordingly, at box 6215, it is checked whether one or more pre-determined events are detected in the sensor output of the multiple sensors. In some examples, such one or more predetermined events are associated with at least one of the multiple disturbances exceeding a certain predetermined threshold; this corresponds to the sensor output crossing a respective threshold. In further examples, it is checked whether the one or more compensation signals exceed a certain threshold. An alternative example of such one or more predetermined events is detection of an anomaly in the sensor output. In some examples, an anomaly detector algorithm is used: Examples include cluster-based anomaly detection or autoencoder neural networks. Such anomaly detector algorithms can be trained in an unsupervised manner.

If one or more predetermined events are not detected at box 6215, then box 6205 is re-executed, i.e., the disturbance is measured again and compensation signals are further applied. On the other hand, if an excess disturbance is detected at box 6215, the beam is blanked at box 6220. For instance, the inspection or manipulation mode is aborted. Alternatively or additionally, a warning message is output via an HMI. The respective sensor outputs that led to execution of box 6220 are logged in some examples. A safe mode is entered that may be manually exited by a user, according to some examples.

Beam blanking can be executed at comparatively low latency, to avoid damage of the manipulated sample. For instance, typically determining one or more compensation signals will require significant time, e.g., to perform a look-up operation or calculate the compensation signal. Accordingly, beam blanking is, in some examples, executed at a lower latency than such determining of one or more compensation signals. Upon executing the beam blanking, it is possible to resolve any sources of disturbances; and continue the repair task at a later point in time when the disturbances have been reduced.

As a general rule, the decision making at box 6215 is based on other sensor signals than the sensor signals that are considered by the logic of box 6210 according to some examples. For instance, it has been found that the following physical quantities are particularly suited for detecting an excess disturbance at box 6215: acoustic vibration; vibration; environmental pressure; environmental pressure change. On the other hand, the following physical quantities have been found to be particularly suited for determining one or more compensation signals to counteract the beam offset: magnetic field; environmental temperature; environmental pressure; environmental pressure change.

FIG. 11 schematically illustrates an example implementation of a charged particle beam device such as the charged particle beam device 100 discussed above. The scenario of FIG. 11 pertains to a charged particle beam repair device (or simply repair device). FIG. 11 shows a schematic sectional view through some important components of one example of a repair device 11120 which can be used to identify and repair a defect 11160 of a photolithographic mask (as an example of a repair object). A sample 11405 can be arranged in the form of a photolithographic mask 11110, for example, on the sample stage 11402 (corresponding to the sample stage 113). The photomask can have one or a plurality of defects 11160 in the form of excess material (“dark defects”) and/or missing material (“clear defects”). The defect of the photolithographic mask is not reproduced in FIG. 11. The defect or generally defects of excess or missing material can be scanned and thus analyzed with the aid of a charged particle beam. Furthermore, defects can be corrected by use of particle beam-induced processing process. For this purpose, the repair device 11120 comprises a scanning electron microscope (SEM, Scanning Electron Microscope) 11410. Moreover, defects of excess material can be repaired by use of a measuring tip of a scanning probe microscope 11480. Therefore, the repair device 11120 comprises one or a plurality of scanning probe microscopes 11480 typically in the form of an atomic force microscope (AFM, Atomic Force Microscope) 11480.

In the SEM 11410 in FIG. 11, an electron gun implementing a beam source 11412 generates an electron beam 11415, which the imaging elements (implementing a beam deflection unit) arranged in the electron column 11417, said imaging elements not being illustrated in FIG. 11, direct/deflect as a focused electron beam 11415 onto the sample 11405 at the location 11422, which sample—as already explained—can comprise a photolithography mask. The sample 11405 is arranged on a sample stage 11402. A sample stage 11402 is also known as a “stage” in the art. As symbolized by the arrows in FIG. 11, a positioning unit 11407 can move the sample stage 11402 about six axes relative to the column 11417 of the SEM 11410. The movement of the sample stage 11402 by the positioning unit 11407 can be effected with the aid of micromanipulators, for example, which are not shown in FIG. 11.

At the processing location 11422, the particle beam 11415 impinges on the sample 11405. Thus, the positioning unit 11407, by virtue of the displacement of the sample stage 11402 perpendicularly to the beam axis of the electron beam 11415, makes it possible firstly to analyze defects of the photomask by generating an image of the defect (inspection task). For this purpose, the imaging elements of the column 11417 of the SEM 11410 can scan the electron beam 11415 over the sample 11405. By use of the tilting and/or rotation of the sixth-axis sample stage 11402, the latter makes it possible to examine one or a plurality of defects from different angles or perspectives. The respective position of the various axes of the sample stage 11402 can be measured by interferometry (not reproduced in FIG. 11). The positioning unit 11407 is controlled by signals of a control unit 11425. The control unit 11425 can be part of a computer system 11430 of the repair device 11120. The control unit 11425 implements, in some examples, the control unit 119 or the control unit 130 (cf. FIG. 6).

The repair device 11120 can furthermore comprise one or more sensors that make it possible to characterize both a current state of the SEM 410 and the process environment in which the SEM 11410 is used (for instance a vacuum environment). For instance, vibration, temperature, pressure, respective differentials or change rates (over time) could be measured.

The electron beam 11415 can furthermore be used for inducing a particle beam-induced processing process for correcting identified defects for example in the context of an electron beam-induced etching process EBIE (Electron Beam Induced Etching) for removing dark defects and/or an electron beam-induced deposition process EBID (Electron Beam Induced Deposition) for correcting clear defects. In addition, in the repair device 11120 in FIG. 11, the electron beam 11415 can be used for analyzing a repaired location of a photomask.

The electrons backscattered from the electron beam 11415 by the sample 11405 and the secondary electrons produced by the electron beam 11415 in the sample 11405 are registered by the detector 11420. If the sample 11405 comprises the photomask, the detector 11420 identifies secondary electrons emitted during the scanning of absorbent strips arranged on the photomask for lithography purposes. The detector 11420 that is arranged in the electron column 11417 is referred to as an “in lens detector.” The detector 11420 can be installed in the column 11417 in various embodiments. The detector 11420 can also be used for detecting the electrons backscattered from one or a plurality of defects 11160 of the mask 11110. The detector 11420 is controlled by a control unit 11425 of a computer system 11430 of the device 120. For instance, the computer system 11430 can implement the control unit 130. It would be possible that the embedded control unit 119 is implemented by the control unit 11425.

The repair device 11120 can include a second detector 11445. The second detector 11445 is designed to detect electromagnetic radiation, particularly in the x-ray range. As a result, the second detector 11445 makes it possible to analyze the material composition of the sample, e.g., the photolithography mask, i.e., the substrate thereof, the absorbent strips, and/or one or a plurality of defects. The detector 11445 is likewise controlled by the control unit 11425.

The control unit 11425 of the computer system 430 (it could also be separate from the computer system 430) can set the parameters of the electron beam 11415 for inducing a deposition process for removing clear defects and/or an EBIE process for etching dark defects.

Furthermore, the computer system 11430 has an evaluation unit 11435. The evaluation unit 11435 receives the measurement data of the detector(s) 11420, 11445. The evaluation unit 11435 can generate from the measurement data, for example from secondary electron contrast data, images in a greyscale representation or a greyscale value representation, which are represented on a monitor 11432. In addition, the computer system 11430 comprises an interface 11437, via which the computer system 11430 can transmit to further processing devices. Furthermore, the computer system 11430 of the repair device 11120 can receive one or a plurality of processed or evaluated images and/or one or a plurality of superimposed images from the evaluation device.

As already explained above, the electron beam 11415 of the modified SEM 11410 can be used for inducing an electron beam-induced processing process/manipulation. As likewise already explained above, defects of the sample 11405 can be corrected by use of an electron beam-induced manipulation. In order to carry out these processes, the exemplary scanning electron microscope 11410 of the repair device 11120 in FIG. 11 has three different supply containers 11450, 11460 and 11470.

The first supply container 11450 stores a first precursor gas in the form of a deposition gas, for example a metal carbonyl, for instance chromium hexacarbonyl (Cr(CO)₆), or a carbon-containing precursor gas, such as pyrene, for instance. With the aid of the precursor gas stored in the first supply container 11450, material can be deposited on the sample 11405 or the mask in a local chemical reaction, with the electron beam 11415 of the SEM 11410 acting as an energy supplier in order to split the precursor gas stored in the first supply container 11450 preferably into chromium atoms and carbon monoxide molecules at the location at which the material is intended to be deposited, i.e. at a location of a clear defect. This means that an EBID process for correcting defects of the photomask is carried out by the combined provision of an electron beam 11415 and a precursor gas. The modified SEM 11410 in combination with the first supply container 11450 or the deposition gas stored therein forms a repair device 11120.

In the repair device 11120 illustrated in FIG. 11, the second supply container 11460 stores a precursor gas in the form of an etching gas, which makes it possible to perform a local electron beam induced etching (EBIE) process. Defects of excess material or dark defects can be removed from the photolithographic mask 11110 (or another sample, e.g., a semiconductor wafer) with the aid of an electron beam-induced etching process. A precursor gas in the form of an etching gas can comprise for example xenon difluoride (XeF₂), chlorine (Cl₂), oxygen (O₂), ozone (O₃), water vapor (H₂O), hydrogen peroxide (H₂O₂), dinitrogen monoxide (N₂O), nitrogen monoxide (NO), nitrogen dioxide (NO₂), nitric acid (HNO₃), ammonia (NH₃) or sulfur hexafluoride (SF₆) or a combination thereof. Consequently, the modified SEM 11410 in combination with the second supply container 11460 or the precursor gas stored therein forms a repair device 11120.

An additive gas can be stored in the third supply container 11470, said additive gas, where necessary, being able to be added to the etching gas kept available in the second supply container 11460 or to the deposition gas stored in the first supply container 11450. Alternatively, the third supply container 11470 can store a precursor gas in the form of a second deposition gas or a second etching gas.

In the scanning electron microscope 11410 illustrated in FIG. 11, each of the supply containers 11450, 11460 and 11470 has its own control valve 11452, 11462 and 11472 in order to monitor or control the amount of the corresponding gas that is provided per unit time, i.e., the gas volumetric flow at the location 11422 of the incidence of the electron beam 11415 on the sample 11405. The control valves 11452, 11462 and 11472 are controlled and monitored by the control unit 11425. By this means, it is possible to set the partial pressure conditions of the gas or gases provided at the processing location 11422 for carrying out an EBID and/or EBIE process in a wide range, during operation (cf. FIG. 7: box 6010).

Furthermore, in the exemplary SEM 11410 in FIG. 11, each supply container 11450, 11460 and 11470 has its own gas feedline system 11454, 11464 and 11474, which ends with a nozzle 11456, 11466 and 11476 in the vicinity of the point of incidence, i.e., the processing location 11422 of the electron beam 11415 on the sample 11405.

The supply containers 11450, 11460 and 11470 can have their own temperature setting element and/or control element, which allows both cooling and heating of the corresponding supply containers 11450, 11460 and 11470. This makes it possible to store and in particular provide the precursor gases of the deposition gas and/or the etching gas at the respectively optimum temperature (not shown in FIG. 11). The control unit 11425 can control the temperature setting elements and the temperature control elements of the supply containers 11450, 11460 and 11470. During the EBID and the EBIE processing processes, the temperature setting elements of the supply containers 11450, 11460 and 11470 can furthermore be used to set the vapor pressure of the process gas(es) stored therein by way of the selection of an appropriate temperature.

The device 11400 can comprise more than one supply container 11450 in order to store precursor gases of two or more deposition gases. Furthermore, the device 400 can comprise more than one supply container 11460 for storing precursor gases of two or more etching gases.

The scanning electron microscope 11410 illustrated in FIG. 11 can be operated under ambient conditions or in a vacuum chamber 11442. Implementing the EBID and EBIE processes necessitates a negative pressure in the vacuum chamber 11442 relative to the ambient pressure. For this purpose, the SEM 11410 in FIG. 11 comprises a pump system 11444 for generating and for maintaining a negative pressure required in the vacuum chamber 11442. With closed control valves 11452, 11462 and 11472, a residual gas pressure of <10⁻⁴ Pa is achieved in the vacuum chamber 11442. The pump system 11444 can comprise separate pump systems (not shown in FIG. 11) for the upper part of the vacuum chamber 11442 for providing the electron beam 11415 of the SEM 11410 and for the lower part or the reaction chamber 11448. A pressure sensor may be provided to monitor the pressure inside and outside of the vacuum chamber 11442. A pressure differential may be monitored.

The SEM 11410 presented in the repair device 11120 in FIG. 11 has a single electron beam 11415. However, it is also possible for the SEM 11410 to have a source of a second particle beam. The second particle beam can comprise a photon beam and/or an ion beam (not shown in FIG. 11). Furthermore, the SEM 11410 can have two or more electron beams 11415 in order to be able to carry out in parallel two or more particle beam-induced processing processes or two or more analysis processes of two or more defects.

Additionally, the exemplary repair device 11120 illustrated in FIG. 11 comprises a scanning probe microscope 11480 which, in the repair device 11120, is embodied in the form of a scanning force microscope (SFM) 11480 or an atomic force microscope (AFM) 11480. The scanning probe microscope 11480 can be used for scanning one or a plurality of defects 11160 of the sample 11405 or of the photomask 11110. Moreover, the scanning probe microscope 11480 can be used for repairing the defects of excess material. For this purpose, the scanning probe microscope 11480 can comprise a first measuring tip for analyzing the sample 11405 and a second measuring tip for processing one or a plurality of defects.

Only the measuring head 11485 of the scanning probe microscope 11480 is illustrated in the repair device 11120 in FIG. 11. In the example in FIG. 11, the measuring head 11485 comprises a holding device 11487. The measuring head 11485 is secured to the frame of the repair device 11120 by use of the holding device 11487 (not shown in FIG. 11). A piezo-actuator 11490 which enables a movement of the free end of the piezo-actuator in three spatial directions (not illustrated in FIG. 11) is attached to the holding device 11487 of the measuring head 11485. A probe 11492 comprising a cantilever 11494 or lever arm 11494 and a measuring tip 11495 is secured to the free end of the piezo-actuator 11490. The free end of the cantilever 11494 of the probe 11492 has the measuring tip 11495.

Next, in connection with FIG. 12 and FIG. 13, options for positioning sensors 800 that can be used to measure disturbances of physical quantities that each affect a beam offset of the beam 11415 of the repair device 11120 will be disclosed. The repair device 11120 is only schematically illustrated, at a higher level of abstraction if compared to FIG. 11 in FIG. 12 and FIG. 13. FIG. 12 and FIG. 13, beyond what is disclosed in FIG. 11, also discloses a beam blanker 11801 that can be used to blank the beam 11415, as well as an aperture 11802 and electric coils 11803 and 11804 for deflecting the beam (i.e., forming optics of the beam deflection unit 112).

In the scenario of FIG. 12, the sensors 800 are arranged outside of the vacuum chamber 11442 of the repair device 11120. In the scenario FIG. 13, the sensors 800 are arranged inside the vacuum chamber 11442 of the repair device 11120. Combinations are possible, i.e., some of the sensors can be arranged inside the vacuum chamber while other sensors can be arranged outside of the vacuum chamber.

FIGS. 14 and 15 illustrates a mask repair operation at the high precision achievable with the repair device 11120 of the preceding FIGs. In a first step illustrated at FIG. 14, a mask defect 1471.1 in an absorber line 1453 on a substrate layer 1451 of the mask is determined with high precision. Using the inspection mode, a precise determination of the extension of the defect 1471.1 is determined, including at least a slope angle 1473.1 of the defect 1471.1. The position, a deviation to a target range 1475 of the edge position and the extensions of the defect can be determined with an accuracy below 1 nm, preferably even below 0.5 nm. The missing volume of material to be deposited in a repair operation can be determined with high accuracy. In the repair step (manipulation mode), utilizing for example low energy electron beam assisted deposition of material from precursor gases provided by the gas supply apparatus, the defect 1471.1 is filled with for example chromium, forming the repaired defect 1477. This is illustrated in FIG. 15. The performance of the repair operation is then verified by the apparatus in inspection mode. A resulting edge position of the line 1453 and a slope angle 1473.2 of the line edge can be obtained with high accuracy. Thereby it is maintained that a repair operation is performed very well within the specification requirement for masks, including the strong requirements for EUV masks with edge positions below 0.5 nm or even less. The steps of repair and verification can also be performed iteratively. Such manipulation is not limited to missing material in a mask layer but can also be applied in analogy to the removal of excess material in mask layer. Further, the manipulation is not limited to mask repair, but also to circuit edit operations at processed wafers. In both examples, layer material is removed by electron beam induced etching or deposited by electron beam induced deposition, and an end-pointing of the processing with high precision is required.

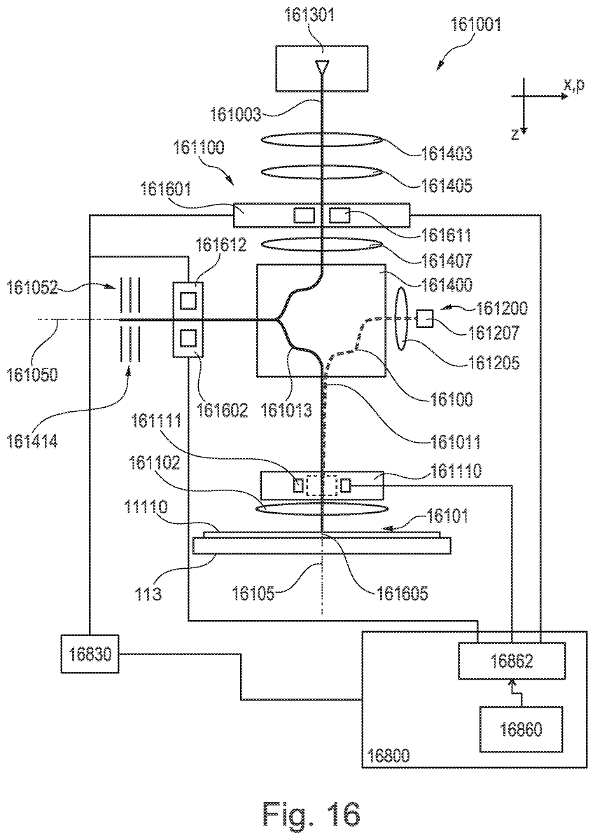

FIG. 16 schematically illustrates an example implementation of a charged particle beam device such as the charged particle beam device 100 discussed above.

The charged particle device 161001 in FIG. 16 is a low-energy corrected electron microscope with reduced aberrations, as described in German patent application, DE 10 2019 214 936, filed on Sep. 27, 2019, which is hereby incorporated by reference. Generally, a low-energy corrected electron microscope comprises correction means for chromatic aberration (CC), spherical aberration (CS), and optionally also field curvature (FC). A low-energy corrected single beam charged particle microscope 161001 comprises a beamlet generator 161301 for generating a single primary charged particle beamlet 161003, an object irradiation unit 161100 for illuminating an image subfield on a surface of a sample 11110 (e.g., a lithography mask or a semiconductor wafer including semiconductor structures) arranged in an object plane 16101, thereby generating during use a secondary electron beamlet 161009 emitting from a focus point 161605 of the primary beamlet 161003 within the image subfield. The subfield has typically a lateral extension of at least 5 μm, preferably 8 μm, 12 μm or more. The object irradiation unit 161100 further comprises first to third electrostatic or magnetic lenses 161403, 161405 and 161407 and an objective lens 161102. The charged particle microscope 161001 further comprises a detection unit 161200 for acquisition during use a digital image of the image subfield of the surface of the sample. The detection unit 161200 comprises an electron sensor 161207 and optional electrostatic or electromagnetic deflection elements 161205. The charged particle microscope 161001 further comprises an electro-magnetic beam splitting system 161400 for guiding the primary beamlet 161003 along the primary beam-path (solid line 161013) and guiding the secondary beamlet 161009 along the secondary beam-path (dashed line, 161011). The secondary beamlet 161009, collected by objective lens 161102, is propagating opposite to the primary beamlet 161003 und therefore separated from the primary beamlet 161003 by the magnetic beam splitting system 161400. The charged particle microscope 161001 further comprises a long stroke raster scanner 161110. The raster scanner 161110 (forming a beam deflection unit) comprises at least a first set of deflection electrodes 161111. The charged particle microscope 161001 further comprises a control unit 16800 (implementing the control unit 119 or the control unit 130). The charged particle microscope 161001 further comprises at least a first corrector 161601 for correction the primary charged particle beamlet 161003. The charged particle system 161001 further comprises a correction system 161052 with a second optical axis 161050 at an angle to the optical axis 16105. The beam splitter system 161400 guides the primary beamlet in direction of the second optical axis 161050 into a correction system 161052. The correction system comprises an electrostatic mirror 161414, which reflects the primary beamlet back to the beam splitter system 161400. In an example, a second corrector 161602 is arranged in the correction system 161052, with correction electrodes 161612. With a low-energy corrected single beam charged particle microscope 161001, electron imaging with kinetic energies below 400 eV, preferable below 300 eV, even more preferably below 200 eV, or even more preferably below 150 eV, is enabled and a high resolution below 2 nm, preferable below 1.5 nm, even more preferably below 1 nm is achieved by utilizing primary electrons of low landing energy and the correction means of the low-energy electron microscope.

The charged particle beams are again arranged in a vacuum chamber (not shown in FIG. 16). The sensors can be arranged inside and/or outside of the vacuum chamber, as previously discussed in connection with FIGS. 14 and 15.

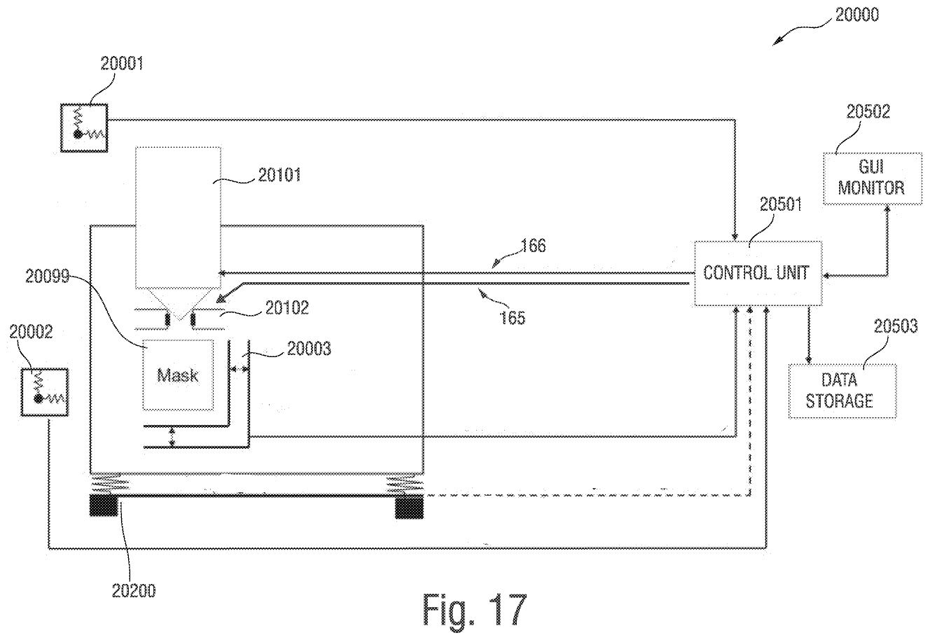

FIG. 17 illustrates an example charged particle beam device 20000. The charged particle beam device 20000 corresponds to the charged particle beam device 100 illustrated in FIG. 6. For example, the charged particle beam device 20000 can be a charged particle beam repair device.

Illustrated is an optics column 20101 (including a beam source, a beam deflection unit, a detector, etc.) as well as a mask 20099 that is currently under repair. Also illustrated is a laser interferometric sample stage 20003 providing multiple degrees of freedom such as lateral translation as well as rotation. Further illustrated is an additional beam deflection unit 20102, here provided as a retrofit at the outside of the optics column 20101. The beam deflection unit 20102 can be an electrostatic or magnetic beam deflection unit. Also shown is an active damping system 20200.

Accordingly, the charged particle beam device 20000 includes two beam deflection units, a first one in the optics column 20101 and a second beam deflection unit 20102 attached thereto. It is possible that different tasks are handled by the two beam deflection units. The first beam deflection unit can deflect the beam in accordance with imaging or manipulation. Typically, imaging is implemented using an electrostatic beam deflection unit and manipulation is implemented using a magnetostatic beam deflection unit. I.e., the respective control signals can be fixedly predefined prior to commencing the imaging or manipulation task. The second deflection unit 20102 can be controlled to compensate for disturbances.

For instance, a combination of an electrostatic and a magnetostatic beam deflection unit may be used. Furthermore, illustrated is a control unit 20501 that can be configured to process signals in real time. The control unit 20501 is configured to obtain multiple sensor signals from multiple 3-axis accelerometer sensors 20001, 20002. These 3-axis accelerometer sensors 20001, 20002 may be positioned outside of a vacuum chamber in which the optics column 20101 is arranged. It is optionally possible to obtain sensor signals from the laser interferometric sample stage 200003 and/or the damping system 20200 (e.g., including position of the damping system, velocity of the damping system or other signals).

Based on these multiple sensor signals it is then possible to determine a compensation signal, e.g., using a machine-trained transfer function or a transfer function that specifies a proportional dependency and/or a MIMO transfer function.

Such compensation signal 165 is then provided to the beam deflection unit 20102. The control unit 20501 also provides control signals 166 to the optics column 20101, to thereby control the beam deflection unit and the optics column 20101 to execute an imaging task and/or a manipulation task, i.e., implement an electron-beam-induced manipulation of a sample such as a mask.

Also illustrated is a graphical user interface 20502, e.g., implemented on a display. It is possible to output current information that is determined based on the one or more sensor outputs, e.g., health information for the charged particle beam device 2000.

Further illustrated is a data storage 20503. It is possible that a log file is maintained and updated based on the sensor output and stored in the data storage 20503. For instance, such log file can be periodically updated. It would be possible that an event-triggered update of the log file is executed. For instance, an amplitude of one or more disturbances determined based on the sensor output can be indicated by the log file. A strength of vibrations detected can be stored in the log file.

Summarizing, techniques have been disclosed that facilitate compensation of multiple disturbances caused by multiple physical quantities, the disturbances affecting a beam offset of a beam of a charged particle beam device. Such compensation is executed during an imaging mode or a manipulation mode, e.g., for mask repair or circuit added. Such compensation, in particular, is possible in case the disturbances/the beam offset is within a certain predetermined range. Else, if the disturbances cannot be compensated, the imaging mode or the manipulation mode is stopped according to examples, e.g., by blanking the beam and/or by closing precursor gas supply valves. A warning is output according to examples. Once the disturbances have resolved, the operation is restarted at the point of the process at which the stopping has occurred. Using the techniques disclosed herein, an increased quality for imaging tasks or manipulation tasks is achieved. The risk for damaging expensive lithography masks or semiconductor devices subject to a manipulation can be reduced.

An active system has been disclosed which, by use of a real-time computer (and/or FPGA-based controller) detects interference signals (e.g., mechanical, acoustic and electromagnetic interference signals), determines one or more compensation signals and uses the beam deflection unit to adjust the electron beam electron beam in the correct phase.

Furthermore, techniques have been disclosed that facilitate using a sensor output of multiple sensors for a prediction of the future behavior of the charged particle beam device. For instance, the sensor output can be stored in a data repository and multiple time series can be correlated with each other. Correlations can be found and repetitive fingerprints can be identified. This can be used to make predictions for the future behavior of the charged particle beam device. Predictive maintenance information can be determined, e.g., by acquiring the acoustic frequency spectrum and/or acoustic noise pressure using microphones, e.g., a continuous increasing noise level at certain frequencies in the sound spectrum can be detected, which can be indicative of failure of one or more parts of the charged particle beam device such as the pump. To improve service activities and subsequent troubleshooting, it is important to know the vibration status (or the influence of external disturbances such as magnetic fields and acoustics) at certain time stamps. Such information can be provided as part of the predictive maintenance information or, more generally, a log file determined based on the sensor output. Continuous or event-triggered logging makes it possible to create a database to predict possible future service events (predictive maintenance)

The sensor output, in various examples, is analyzed using machine learning algorithms such as deep neural networks. Training can be reiterated from time to time, based on training data that is acquired during a calibration phase. Thus, the accuracy can be continuously increased. Furthermore, site-specific training based on site-specific calibration becomes possible.

Summarizing, at least the following examples—as defined by the following clauses—have been disclosed.

Clause 1. A charged particle beam device, comprising a beam source, at least one beam deflection unit, and a sample stage, the at least one beam deflection unit being configured to deflect a beam of charged particles originating from the beam source to position the beam on the sample stage, the charged particle beam device including:
one or more sensors configured to measure one or more disturbances of one or more physical quantities that each affect a beam offset of the beam on the sample stage,
at least one control unit configured to determine, based on a sensor output of the one or more sensors, one or more compensation signals to counteract the beam offset, wherein the at least one control unit is configured to provide the one or more compensation signals to at least one of the beam source, the at least one beam deflection unit, the sample stage, or one or more compensator modules.

Clause 2. The charged particle beam device of clause 1,
wherein the at least one control unit is configured to determine a predictive component of the beam offset based on the sensor output of the one or more sensors and to determine the one or more compensation signals based on the predictive component of the beam offset.

Clause 3. The charged particle beam device of clause 2,
wherein the sensor output of at least one of the one or more sensors includes respective time series data,
wherein the at least one control unit is configured to determine the predictive component based on an analysis of the time series data of the sensor output of the at least one of the one or more sensors.

Clause 4. The charged particle beam device of clause 3,
wherein the analysis of the time series data comprises finding fingerprints of one or more predetermined disturbance events in the time series data, and/or applying a recurrent neural network such as a Long Short Term Memory Network.

Clause 5. The charged particle beam device of clause 4,
wherein the at least one control unit is configured to selectively activate a calibration phase, wherein, when operating in the calibration phase, the at least one control unit is configured to populate a repository with the fingerprints of the one or more disturbance events, e.g., based on at least one of identifying respective repetitions of the fingerprints in the time series data or obtaining user input data that is indicative of a respective one of the one or more disturbance events.

Clause 6. The charged particle beam device of clause 4 or 5,
wherein the at least one control unit is configured to selectively activate a calibration phase, wherein, when operating in the calibration phase, the at least one control unit is configured to train a predictive model based on the time series data measured during the calibration phase to find the fingerprints and to thereby enable the predictive model to determine the predictive component.

Clause 7. The charged particle beam device of any one of the preceding clauses,
wherein the at least one control unit is further configured to predict, based on at least one of the sensor output or the one or more compensation signals, an accuracy of operation of the charged particle beam device during a prediction time duration.

Clause 8. The charged particle beam device of clause 7,
wherein the at least one control unit is further configured to selectively abort operation of the charged particle beam device depending on the accuracy of operation, e.g., by blanking the beam.

Clause 9. The charged particle beam device of any one of the preceding clauses,
wherein the one or more disturbances comprise multiple disturbances,
wherein the at least one control unit is configured to determine the one or more compensation signals based on cross-dependencies between the multiple disturbances.

Clause 10. The charged particle beam device of clause 9,
wherein the at least one control unit is configured to determine the one or more compensation signals based on a cross dependency between temperature-induced disturbances and pressure-induced disturbances.

Clause 11. The charged particle beam device of any one of the preceding clauses,
wherein the at least one control unit is configured to determine the one or more compensation signals based on a pre-trained algorithm.

Clause 12. The charged particle beam device of clause 11,
wherein the pre-trained algorithm comprises a deep neural network such as a convolutional neural network.

Clause 13. The charged particle beam device of clause 11,
wherein the pre-trained algorithm comprises a machine learning algorithm.

Clause 14. The charged particle beam device of any one of the preceding clauses,
wherein the at least one control unit is configured to determine the one or more compensation signals based on pre-parameterized functional dependencies.

Clause 15. The charged particle beam device of any one of the preceding clauses,
wherein the at least one control unit is configured to determine the one or more compensation signals using a lookup table linking the sensor output with the one or more compensation signals.

Clause 16. The charged particle beam device of clause 15,
wherein the lookup table is retrieved from a device-specific repository associated with the charged particle beam device.

Clause 17. The charged particle beam device of clause 15,
wherein the lookup table is retrieved from a cloud storage repository associated with multiple charged particle beam devices.

Clause 18. The charged particle beam device of any one of the preceding clauses,
wherein the multiple physical quantities are selected from the group comprising: acoustic vibration; vibration; pressure; humidity; temperature; laminar air flow; turbulent air flow; a differential quantity; a change rate of a physical quantity; a vector quantity; a scalar quantity.

Clause 19. The charged particle beam device of any one of the preceding clauses,
wherein the one or more sensors comprise at least one sensor for measuring a temperature or pressure of a cooling liquid.

Clause 20. The charged particle beam device of any one of the preceding clauses,
wherein at least one of the one or more sensors is arranged inside a vacuum chamber of the charged particle beam repair device.

Clause 21. The charged particle beam device of any one of the preceding clauses,
wherein at least one of the one or more sensors is arranged outside of a vacuum chamber of the charged particle beam repair device.

Clause 22. The charged particle beam device of any one of the preceding clauses,
wherein the one or more sensors comprise at least one sensor for measuring a pressure differential or temperature differential between two or more parts of the charged particle beam repair device.

Clause 23. The charged particle beam device of any one of the preceding clauses,
wherein the one or more disturbances are selected from the group comprising: direct disturbances affecting the beam offset by deflecting the beam; indirect disturbances affecting the beam offset by impacting one or more parts of the charged particle beam device.

Clause 24. The charged particle beam device of any one of the preceding clauses,
wherein the beam offset comprises at least one of a placement offset or a focal offset of the beam.

Clause 25. The charged particle beam device of any one of the preceding clauses,
wherein the at least one control unit is configured to monitor the sensor output of a least one of the one or more sensors or a further sensor output of at least one further sensor and selectively blank the beam based on said monitoring.

Clause 26. The charged particle beam device of clause 25,
wherein the at least one control unit is configured to selectively blank the beam at lower latency if compared to said determining the one or more compensation signals.

Clause 27. The charged particle beam device of any one of the preceding clauses,
wherein the at least one control unit is configured to provide the one or more compensation signals when the charged particle beam device operates in the manipulation mode such as an electron beam induced etching or deposition mode, the manipulation mode comprising repairing or editing semiconductor devices on a wafer mounted to the sample stage.

Clause 28. The charged particle beam device of any one of the preceding clauses,
wherein the charged particle beam device is a charged particle beam repair device.

Clause 29. The charged particle beam device of any one of the preceding clauses,
wherein the charged particles are electrons or ions such as Helium or Neon ions.

Clause 30. The charged particle beam device of any one of the preceding clauses,
wherein the charged particle beam device is a combined focused ion beam and an electron microscope cross-beam device.

Clause 31. The charged particle beam device of any one of the preceding clauses,
wherein the charged particle beam device is a charged particle beam repair device,
wherein the charged particle beam repair device further comprises a precursor gas source,
wherein the at least one control unit is configured to provide, to the beam source, the at least one beam deflection unit, and the precursor gas source, control signals to implement an electron-beam-induced manipulation of a sample mounted to the sample stage,
wherein the at least one control unit is configured to provide the one or more compensation signals during the electron-beam-induced manipulation.

Clause 32. The charged particle beam device of any one of the preceding clauses,
wherein the at least one control unit is configured to provide the one or more compensation signals while the charged particle beam device operates in an imaging mode that comprises imaging structures of the sample mounted to the sample stage.

Clause 33. The charged particle beam device of any one of the preceding clauses,
wherein the at least one control unit determines the one or more compensation signals in accordance with a linear or a nonlinear dependency of the one or more compensation signals on the sensor output.

Clause 34. The charged particle beam device of any one of the preceding clauses,
wherein the one or more disturbances comprise multiple disturbances,
wherein the one or more physical quantities comprise multiple physical quantities.

Clause 35. The charged particle beam device of any one of the preceding clauses,
wherein the one or more compensator modules are selected from the group comprising: external, i.e., outside of a vacuum chamber or housing of the charged particle beam device, coils for applying magnetic fields; external electric field plates for applying electric fields; Helmholtz coil pairs; an active cooling or heating element; an active damping element; a pressure-control element such as a pump.

Clause 36. A charged particle beam device comprising a beam source, at least one beam deflection unit, and a sample stage, the at least one beam deflection unit being configured to deflect a beam originating from the beam source to position the beam on the sample stage, the charged particle beam device comprising:
one or more sensors configured to measure one or more disturbances of one or more physical quantities that each affect a beam offset of the beam on the sample stage, and
at least one control unit configured to determine, based on the sensor output of the one or more sensors, metadata that is indicative of one or more compensation operations to counteract the beam offset in image data acquired by the charged particle beam device operating in an imaging mode, and to store the metadata in association with the image data.

Clause 37. The charged particle beam device of clause 36,
wherein the one or more compensation operations are selected from the group comprising: imaging shift; rotation; skew; contrast enhancement; blur reduction.

Clause 38. A method, comprising:
monitoring physical quantities that cause disturbances onto a beam of a charged particle beam device,
based on said monitoring, compensating the disturbances.

Clause 39. The method of clause 38,
wherein said compensating of the disturbances comprises applying a voltage or current to an electronic optics of at least one beam deflection unit of the charged particle beam device, to move the beam in an opposite direction of a beam offset caused by the disturbances.

Clause 40. The method of clause 38 or 39,
wherein said compensating or reducing of the disturbances comprises moving a sample stage of the charged particle beam device in a direction of a beam offset caused by the disturbances.

Clause 41. The method of any one of clauses 38 to 40,
wherein the time latency between said monitoring and said compensating or reducing is less than 50 milliseconds, optionally less than 500 milliseconds, further optionally less than 5 seconds.

Clause 42. The method of any one of clauses 38 to 41,
wherein said compensating or reducing is executed while the charged particle beam device operates in a manipulation mode that comprises an electron-beam-induced etching or deposition of material from or onto a wafer mask.

Clause 43. The method of any one of clauses 38 to 42, further comprising:
based on said monitoring, selectively aborting operation of the charged particle beam device.

Clause 44. The method of clause 43,
wherein said selectively aborting operation of the charged particle beam device comprises blanking the beam.

Clause 45. The method of clause 43 or 44, further comprising:
based on said monitoring, selecting between executing said compensating of the disturbances and executing said aborting operation.

Clause 46. A method of manipulating or imaging a sample mounted to a sample stage of a charged particle beam device, the charged particle beam device comprising a beam source, at least one beam deflection unit, and the sample stage, the at least one beam deflection unit being configured to deflect a beam of charged particles originating from the beam source to position the beam on the sample stage,
wherein the method comprises:
   obtaining a sensor output of one or more sensors of the charged particle beam device, the one or more sensors measuring one or more disturbances of one or more physical quantities that each affect a beam offset of the beam on the sample stage,
   determining, based on the sensor output of the one or more sensors, one or more compensation signals to counteract the beam offset,
   providing the one or more compensation signals to at least one of the beam source, the at least one beam deflection unit, the sample stage, or one or more compensator modules.

Clause 47. The method of clause 46, wherein the method is executed by the control unit of the charged particle beam device of clause 1.

Clause 48. A method of post-processing image data that is acquired by a charged particle beam device that comprises a beam source, at least one beam deflection unit, and a sample stage, the at least one beam deflection unit being configured to deflect a beam of charged particles originating from the beam source to position the beam on the sample stage,
wherein the method comprises:
   obtaining a sensor output from one or more sensors of the charged particle beam device, the one or more sensors measuring one or more disturbances of one or more physical quantities that each affect a beam offset of the beam on a sample stage,
   determining, based on the sensor output of the one or more sensors, metadata that is indicative of one or more compensation operations to counteract the beam offset in image data acquired by the charged particle beam device operating in an imaging mode, and
   post-processing the image data based on the metadata and in accordance with the one or more compensation operations.

Clause 49. The method of clause 48, wherein the method is at least partially executed by the control unit of the charged particle beam device of clause 36.

Furthermore, further examples—as defined by the clauses listed hereinafter—have also been disclosed. These further examples may be combined with the clauses disclosed above, to form further examples.

CLAUSE 1. A charged particle beam repair device (100, 11120, 11410, 161001, 20000) comprising a beam source (111, 11412), at least one beam deflection unit (112, 11417, 20102), a precursor gas source (11456, 11466, 11476, 11450, 11460, 11470, 11452, 11462, 11472), and a sample stage (114, 11402, 20003), the at least one beam deflection unit (112, 11417, 20102) being configured to deflect a beam (90, 91, 92, 93, 94, 95, 11415, 161003, 161009) of charged particles originating from the beam source to position the beam on the sample stage (113, 11402, 20003), the charged particle beam repair device (100, 11120, 11410, 161001, 20000) comprising:
multiple sensors (121, 122, 800) configured to measure multiple disturbances of multiple physical quantities that each affect a beam offset (71, 72, 81) of the beam (90, 91, 92, 93, 94, 95) on the sample stage (114, 11402, 20003),
at least one control unit (119, 130, 11425, 16800, 20501) configured to determine, based on a sensor output (161, 162) of the multiple sensors (121, 122, 800), one or more compensation signals (165) to counteract the beam offset (71, 72, 81),
wherein the at least one control unit (119, 130, 11425, 16800, 20501) is configured to provide, to the beam source (111, 11412), the at least one beam deflection unit (112, 11417, 20102), and the precursor gas source (11456, 11466, 11476, 11450, 11460, 11470, 11452, 11462, 11472) control signals (166) to implement an electron-beam-induced manipulation of a sample (11110, 20099) mounted to the sample stage (113, 11402, 20003),
wherein the at least one control unit (119, 130, 11425, 16800, 20501) is configured to provide, during the electron-beam-induced manipulation, the one or more compensation signals (165) to at least one of the beam source (111, 11412), the at least one beam deflection unit (112, 11417, 20102), the sample stage (114, 11402, 20003), or one or more compensator modules.

CLAUSE 2. The charged particle beam repair device (100, 11120, 11410, 161001, 20000) of CLAUSE 1,
wherein one or more of the multiple sensors are selected from the group comprising: one or more laser interferometers; one or more linear encoders; one or more accelerometers; one or more acoustic sensors; one or more sensors configured to sense one or more components of a magnetic field; one or more sensors configured to sense one or more components of an electric field; one or more sensors configured to supply a signal synchronized with an AC mains voltage; one or more multi-axis accelerometers; and one or more actuators of an active damping system.

CLAUSE 3. The charged particle beam repair device of CLAUSE 1 or 2,
wherein the at least one control unit (119, 130, 11425, 16800, 20501) is configured to determine the one or more compensation signals based on a predefined multi-input multi-output transfer function.

CLAUSE 4. The charged particle beam repair device of any one of the preceding CLAUSEs,
wherein the at least one control unit (119, 130, 11425, 16800, 20501) comprises a proportional control module configured to determine the one or more compensation signals.

CLAUSE 5. The charged particle beam repair device (100, 11120, 11410, 161001, 20000) of any one of the preceding CLAUSEs,
wherein the at least one control unit (119, 130, 11425, 16800, 20501) is configured to determine the one or more compensation signals (165) based on a machine-learning algorithm.

CLAUSE 6. The charged particle beam repair device (100, 11120, 11410, 161001, 20000) of any one of the preceding CLAUSEs,
wherein the at least one beam deflection unit (112, 11417, 20102) comprises a first beam deflection unit and a second beam deflection unit,
   wherein the at least one control unit (119, 130, 11425, 16800, 20501) is configured to provide the control signals (166) to implement the electron-beam-induced manipulation of the sample to the second beam deflection unit,
   wherein the at least one control unit (119, 130, 11425, 16800, 20501) is configured to provide the one or more compensation signals (165) to the first beam deflection unit.

CLAUSE 7. The charged particle beam repair device (100, 11120, 11410, 161001, 20000) of CLAUSE 6,
wherein the second beam deflection unit is an electrostatic beam deflection unit,
wherein the first beam deflection unit is a magnetostatic beam deflection unit.

CLAUSE 8. The charged particle beam repair device (100, 11120, 11410, 161001, 20000) of CLAUSE 6 or 7,
wherein the second beam deflection unit has a higher operating bandwidth than the first beam deflection unit.

CLAUSE 9. The charged particle beam repair device (100, 11120, 11410, 161001, 20000) of any one of the preceding CLAUSEs,
wherein the at least one control unit (119, 130, 11425, 16800, 20501) is configured to maintain a log file based on the sensor output.

CLAUSE 10. The charged particle beam repair device (100, 11120, 11410, 161001, 20000) of any one of the preceding CLAUSEs,
wherein the at least one control unit (119, 130, 11425, 16800, 20501) is configured to determine predictive maintenance information based on the sensor output.

CLAUSE 11. The charged particle beam repair device (100, 11120, 11410, 161001, 20000) of any one of the preceding CLAUSEs,
wherein the at least one control unit (119, 130, 11425, 16800, 20501) is configured to selectively activate a calibration phase (6005),
   wherein, when operating in the calibration phase (6005), the at least one control unit (119, 130, 11425, 16800, 20501) is configured to measure the beam offset based on an appearance of marker structures in images acquired using the charged particle beam repair device (100, 11120, 11410, 161001, 20000),
wherein the marker structures are optionally selected from the group comprising: alignment markers; drift markers.

CLAUSE 12. The charged particle beam repair device (100, 11120, 11410, 161001, 20000) of CLAUSE 11,
wherein the marker structures are attached to the sample.

CLAUSE 13. The charged particle beam repair device (100, 11120, 11410, 161001, 20000) of CLAUSE 11 or 12,
wherein the at least one control unit (119, 130, 11425, 16800, 20501) is configured to output (6117) a warning and/or activate a fault mode if the beam offset exceed a predefined threshold.

CLAUSE 14. The charged particle beam repair device (100, 11120, 11410, 161001, 20000) of any one of CLAUSEs 11 to 13,
wherein the at least one control unit (119, 130, 11425, 16800, 20501) is configured to activate a calibration phase (6005) responsive to scheduling a repair task for the sample (11110, 20099).

CLAUSE 15. The charged particle beam repair device (100, 11120, 11410, 161101) of any one of the preceding CLAUSEs,
wherein at least one of the multiple sensors (121, 122, 800) is arranged outside a vacuum chamber (110) of the charged particle beam repair device (100, 11120, 11410, 161001, 20000).

CLAUSE 16. A charged particle beam device (100, 11120, 11410, 161001, 20000) comprising a beam source, at least one beam deflection unit (112, 11417, 20102), and a sample stage (114, 11402, 20003), the at least one beam deflection unit (112, 11417, 20102) being configured to deflect a beam originating from the beam source to position the beam on the sample stage (114, 11402, 20003), the charged particle beam device (100, 11120, 11410, 161001, 20000) comprising:
multiple sensors (121, 122, 800) configured to measure multiple disturbances of multiple physical quantities that each affect a beam offset (71, 72, 81) of the beam (90, 91, 92, 93, 94, 95) on the sample stage (114, 11402, 20003), and
at least one control unit (119, 130, 11425, 16800, 20501) configured to determine, based on a sensor output (161, 162) of the multiple sensors (121, 122, 800), meta data indicative of one or more compensation operations to counteract the beam offset (71, 72, 81) in image data acquired by the charged particle beam device operating in an imaging mode, and to store the meta data in association with the image data.

CLAUSE 17. The charged particle beam device (100, 11120, 11410, 161001, 20000) of CLAUSE 16, wherein the meta data is predictive maintenance information.

CLAUSE 18. The charged particle beam device (100, 11120, 11410, 161001, 20000) of CLAUSE 16 or 17,
wherein the at least one control unit (119, 130, 11425, 16800, 20501) is configured to update the meta data event-triggered and/or continuously.

CLAUSE 19. A method of manipulating a sample (11110, 20099) mounted to a sample stage of a charged particle beam repair device (100, 11120, 11410, 161001, 20000), the charged particle beam repair device comprising a beam source, at least one beam deflection unit, a precursor gas source, and the sample stage, the at least one beam deflection unit being configured to deflect a beam of charged particles originating from the beam source to position the beam on the sample stage,
wherein the method comprises:
   obtaining a sensor output of multiple sensors of the charged particle beam repair device, the multiple sensors measuring multiple disturbances of multiple physical quantities that each affect a beam offset of the beam on the sample stage,
   determining, based on the sensor output of the multiple sensors, one or more compensation signals to counteract the beam offset,
   providing, to the beam source, the at least one beam deflection unit, and the precursor gas source control signals to implement an electron-beam-induced manipulation of the sample,
   providing, during the electron beam-induced-manipulation, the one or more compensation signals to at least one of the beam source, the at least one beam deflection unit, the sample stage, or one or more compensator modules.

CLAUSE 20. The method of CLAUSE 19, wherein the method is executed by the control unit of the charged particle beam repair device of CLAUSE 1.

CLAUSE 21. A method of post-processing image data acquired by a charged particle beam device that comprises a beam source, at least one beam deflection unit and a sample stage, the at least one beam deflection unit being configured to deflect a beam of charged particles originating from the beam source to position the beam on the sample stage,
wherein the method comprises:
   obtaining a sensor output from multiple sensors of the charged particle beam device, the multiple sensors measuring multiple disturbances of multiple physical quantities that each affect a beam offset of the beam on the sample stage,
   determining, based on the sensor output of the multiple sensors, meta data indicative of one or more compensation operations to counteract the beam offset in image data acquired by the charged particle beam device operating in an imaging mode, and
   post-processing the image data based on the meta data and in accordance with the one or more compensation operations.

CLAUSE 22. A charged particle beam device (100, 11120, 11410, 161001, 20000) comprising a beam source (111, 11412), multiple beam deflection units (112, 11417, 20102), and a sample stage (114, 11402, 20003), each of the multiple beam deflection unit (112, 11417, 20102) being configured to deflect a beam (90, 91, 92, 93, 94, 95, 11415, 161003, 161009) of charged particles originating from the beam source to position the beam on the sample stage (113, 11402, 20003), the charged particle beam device (100, 11120, 11410, 161001, 20000) comprising:
at least one sensor (121, 122, 800) configured to measure at least one disturbance of at least one physical quantity that affects a beam offset (71, 72, 81) of the beam (90, 91, 92, 93, 94, 95) on the sample stage (114, 11402, 20003),
at least one control unit (119, 130, 11425, 16800, 20501) configured to determine, based on a sensor output (161, 162) of the at least one sensor (121, 122, 800), one or more compensation signals (165) to counteract the beam offset (71, 72, 81),
wherein the at least one control unit (119, 130, 11425, 16800, 20501) is configured to provide, to the beam source (111, 11412) and a first one of the multiple beam deflection units (112, 11417, 20102), control signals (166) to implement an imaging of a sample (11110, 20099) mounted to the sample stage (113, 11402, 20003),
wherein the at least one control unit (119, 130, 11425, 16800, 20501) is configured to provide, during the imaging, the one or more compensation signals (165) to a second one of the multiple beam deflection units (112, 11417, 20102).

CLAUSE 23. The charged particle beam device (100, 11120, 11410, 161001, 20000) of CLAUSE 22,
wherein the first one of the multiple beam deflection units is a magnetostatic beam deflection unit,
wherein the second one of the multiple beam deflection units is an electrostatic beam deflection unit.

CLAUSE 24. The charged particle beam device (100, 11120, 11410, 161001, 20000) of CLAUSE 22 or 23,
wherein the first one of the multiple beam deflection units has a first operating bandwidth,
wherein the second one of the multiple beam deflection units has a second operating bandwidth, the second operating bandwidth being larger than the first operating bandwidth.

CLAUSE 25. A method of imaging a sample mounted to a sample stage of a charged particle beam device, the charged particle beam device comprising a beam source, multiple beam deflection units, and the sample stage, each of the multiple beam deflection units being configured to deflect a beam of charged particles originating from the beam source to position the beam on the sample stage,
wherein the method comprises:
   providing control signals to a first one of the multiple beam deflection units to implement imaging of the sample,
   obtaining a sensor output of one or more sensors of the charged particle beam device, the one or more sensors measuring one or more disturbances of one or more physical quantities that each affect a beam offset of the beam on the sample stage,
   determining, based on the sensor output of the one or more sensors, one or more compensation signals to counteract the beam offset,
   providing the one or more compensation signals to a second one of the multiple beam deflection units.

Although the invention has been shown and described with respect to certain preferred embodiments, equivalents and modifications will occur to others skilled in the art upon the reading and understanding of the specification. The present invention includes all such equivalents and modifications and is limited only by the scope of the appended claims.

For illustration, above various examples have been disclosed in the context of a charged particle beam repair device that executes a repair task using an electron-beam-induced manipulation of a sample, i.e., EBID and/or EBIE. As a general rule, repair tasks could also be employed using physical action using ions, i.e., FIB etching. Furthermore, the techniques disclosed herein are not limited to a charged particle beam repair devices, but can also be used for compensating disturbances during a circuit edit operation at a semiconductor wafer, or during an inspection or measurement task during operation in the imaging mode of a respective imaging charged particle beam device.

For illustration, above various examples have been disclosed in the context of a charged particle beam device employing charged particles such as electrons or ions. Similarly, techniques disclosed herein may be applied to non-charged particle beam devices, e.g., for photon-based microscopes. Here, disturbances can be caused by physical quantities such as seismic variation, acoustics, pressure changes, changes of wind speed, changes of humidity, temperature, etc. Respective beam devices could be, e.g., lasers, x-ray investigation tools, etc. A compensation can be achieved by shifting the sample stage to counteract the beam offset, as has been explained in connection with FIG. 1-FIG. 5.

Furthermore, techniques of active compensation of a beam offset due to disturbances of physical quantities have been disclosed. Such techniques can be applied with passive shielding. For instance, acoustic vibrations, thermal drift, laminar or turbulent airflow can be reduced by encapsulating the beam related parts of the charged particle beam device in a housing. Noise absorbent material can be attached to the housing. Passive or active vibration damping systems can be used to support the housing on the floor.

What is claimed is:

1. A charged particle beam repair device comprising a beam source, at least one beam deflection unit, a precursor gas source, and a sample stage, the at least one beam deflection unit being configured to deflect a beam of charged particles originating from the beam source to position the beam on the sample stage, the charged particle beam repair device comprising:
multiple sensors configured to measure multiple disturbances of multiple physical quantities that each affect a beam offset of the beam on the sample stage,
at least one control unit configured to determine, based on a sensor output of the multiple sensors, one or more compensation signals to counteract the beam offset,
wherein the at least one control unit is configured to provide, to the beam source, the at least one beam deflection unit, and the precursor gas source control signals to implement an electron-beam-induced manipulation of a sample mounted to the sample stage,
wherein the at least one control unit is configured to provide, during the electron-beam-induced manipulation, the one or more compensation signals to at least one of the beam source, the at least one beam deflection unit, the sample stage, or one or more compensator modules,
wherein the at least one control unit is configured to selectively activate a calibration phase,
wherein, when operating in the calibration phase, the at least one control unit is configured to measure the beam offset based on an appearance of marker structures in images acquired using the charged particle beam repair device.

2. The charged particle beam repair device of claim 1,
wherein one or more of the multiple sensors are selected from the group comprising: one or more laser interferometers; one or more linear encoders; one or more accelerometers; one or more acoustic sensors; one or more sensors configured to sense one or more components of a magnetic field; one or more sensors configured to sense one or more components of an electric field; one or more sensors configured to supply a signal synchronized with an AC mains voltage; one or more multi-axis accelerometers; and one or more actuators of an active damping system.

3. The charged particle beam repair device of claim 1,
wherein the at least one control unit is configured to determine the one or more compensation signals based on a predefined multi-input multi-output transfer function.

4. The charged particle beam repair device of claim 1,
wherein the at least one control unit comprises a proportional control module configured to determine the one or more compensation signals.

5. The charged particle beam repair device of claim 1,
wherein the at least one control unit is configured to determine the one or more compensation signals based on a machine-learning algorithm.

6. The charged particle beam repair device of claim 1,
wherein the at least one beam deflection unit comprises a first beam deflection unit and a second beam deflection,
wherein the at least one control unit is configured to provide the control signals to implement the electron-beam-induced manipulation of the sample to the second beam deflection unit,
wherein the at least one control unit is configured to provide the one or more compensation signals to the first beam deflection unit.

7. The charged particle beam repair device of claim 6,
wherein the second beam deflection unit is an electrostatic beam deflection unit,
wherein the first beam deflection unit is a magnetostatic beam deflection unit.

8. The charged particle beam repair device of claim 6,
wherein the second beam deflection unit has a higher operating bandwidth than the first beam deflection unit.

9. The charged particle beam repair device of claim 1,
wherein the at least one control unit is configured to maintain a log file based on the sensor output.

10. The charged particle beam repair device of claim 1,
wherein the at least one control unit is configured to determine predictive maintenance information based on the sensor output.

11. The charged particle beam repair device of claim 1,
wherein the marker structures are at least one of drift markers or alignment markers.

12. The charged particle beam repair device of claim 1,
wherein the marker structures are attached to the sample.

13. The charged particle beam repair device of claim 1,
wherein the at least one control unit is configured to output a warning and/or activate a fault mode if the beam offset exceeds a predefined threshold.

14. The charged particle beam repair device of claim 1,
wherein the at least one control unit is configured to activate a calibration phase responsive to scheduling a repair task for the sample.

15. The charged particle beam repair device of claim 1,
wherein at least one of the multiple sensors is arranged outside a vacuum chamber of the charged particle beam repair device.

16. A charged particle beam device comprising a beam source, multiple beam deflection units, and a sample stage, each of the multiple beam deflection units being configured to deflect a beam of charged particles originating from the beam source to position the beam on the sample stage, the charged particle beam device comprising:
at least one sensor configured to measure at least one disturbance of at least one physical quantity that affects a beam offset of the beam on the sample stage,
at least one control unit configured to determine, based on a sensor output of the at least one sensor, one or more compensation signals to counteract the beam offset,
wherein the at least one control unit is configured to provide, to the beam source and a first one of the multiple beam deflection units, control signals to implement an imaging of a sample mounted to the sample stage,
wherein the at least one control unit is configured to provide, during the imaging, the one or more compensation signals to a second one of the multiple beam deflection units.

17. The charged particle beam device of claim 16,
wherein the first one of the multiple beam deflection units is a magnetostatic beam deflection unit,
wherein the second one of the multiple beam deflection units is an electrostatic beam deflection unit.

18. The charged particle beam device of claim 16,
wherein the first one of the multiple beam deflection units has a first operating bandwidth,
wherein the second one of the multiple beam deflection units has a second operating bandwidth, the second operating bandwidth being larger than the first operating bandwidth.

19. A method of imaging a sample mounted to a sample stage of a charged particle beam device, the charged particle beam device comprising a beam source, multiple beam deflection units, and the sample stage, each of the multiple beam deflection units being configured to deflect a beam of charged particles originating from the beam source to position the beam on the sample stage,
wherein the method comprises:
providing control signals to a first one of the multiple beam deflection units to implement imaging of the sample,
obtaining a sensor output of one or more sensors of the charged particle beam device, the one or more sensors measuring one or more disturbances of one or more physical quantities that each affect a beam offset of the beam on the sample stage,
determining, based on the sensor output of the one or more sensors, one or more compensation signals to counteract the beam offset, and
providing the one or more compensation signals to a second one of the multiple beam deflection units.

20. The method of claim 19, wherein determining the one or more compensation signals comprises determining the one or more compensation signals based on a predefined multi-input multi-output transfer function.
